(19) United States
(12) Patent Application Publication
(10) Pub. No.: US 2025/0234685 A1
(43) Pub. Date: Jul. 17, 2025

(54) MICRON-SCALE LIGHT-EMITTING DEVICE WITH REDUCED-AREA CENTRAL ANODE CONTACT

(71) Applicant: LUMILEDS LLC, San Jose, CA (US)

(72) Inventors: Antonio Lopez-Julia, Vaals (NL); Joseph Flemish, San Jose, CA (US); Xavier Garcia Santiago, Aachen (DE)

(73) Assignee: LUMILEDS LLC, San Jose, CA (US)

(21) Appl. No.: 19/095,242

(22) Filed: Mar. 31, 2025

Related U.S. Application Data
(63) Continuation of application No. PCT/US2023/035929, filed on Oct. 25, 2023.
(60) Provisional application No. 63/419,895, filed on Oct. 27, 2022.

(51) Int. Cl. H10H 20/831; H10H 20/01; H10H 29/80

(52) U.S. Cl. CPC H10H 20/831; H10H 20/032; H10H 29/8321

(57) ABSTRACT

A semiconductor LED includes p-doped, n-doped, and active layers, and has anode and cathode electrical contacts. The p-doped layer has a refractive index of n_{P} and a nonzero thickness less than 10λ₀/n_{P}. The LED is less than 30λ₀/n_{P} wide, and the anode electrical contact is in direct contact with only a central region of the p-doped layer that is separated from the LED side surfaces by more than λ₀/2n_{P}. The LED width, the separation of the anode contact from the LED side surface, and the p-doped layer thickness can result in one or more of (i) increased Purcell factor, (ii) increased extraction efficiency, (iii) increased overall light output efficiency, or (iv) narrowed light output angular distribution.

### CROSS-REFERENCE TO RELATED APPLICATIONS

This application is a continuation of App. No. PCT/US2023/035929 entitled “Micron-scale light-emitting device with reduced-area central anode contact” filed 25 Oct. 2023 in the names of Lopez-Julia et al, which in turn claims priority of U.S. provisional App. No. 63/419,895 entitled “Micron-scale light-emitting device with reduced-area central anode contact” filed 27 Oct. 2022 in the names of Lopez-Julia et al; both of said applications are incorporated herein by reference in their entireties.

### FIELD OF THE INVENTION

The invention relates generally to light emitting diodes.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths.

In some examples the light produced by a semiconductor LED serves as the output light; such LEDs are often referred to as direct emitters, or direct-emitting LEDs. In other examples LEDs may be combined with one or more wavelength converting materials (generally referred to herein as “phosphors”) that absorb light emitted by the LED and in response emit light of a longer wavelength. For such phosphor-converted LEDs (“pcLEDs”), the fraction of the light emitted by the LED that is absorbed by the phosphors depends on the amount of phosphor material in the optical path of the light emitted by the LED, for example on the concentration of phosphor material in a phosphor layer disposed on or around the LED and the thickness of the layer. Phosphor-converted LEDs may be designed so that all of the light emitted by the LED is absorbed by one or more phosphors, in which case the emission from the pcLED is entirely from the phosphors. In such cases the phosphor may be selected, for example, to emit light in a narrow spectral region that is not efficiently generated directly by an LED. Alternatively, pcLEDs may be designed so that only a portion of the light emitted by the LED is absorbed by the phosphors, in which case the emission from the pcLED is a mixture of light emitted by the LED and light emitted by the phosphors. By suitable choice of LED, phosphors, and phosphor composition, such a pcLED may be designed to emit, for example, white light having a desired color temperature and desired color-rendering properties.

Multiple LEDs (direct-emitting or phosphor-converted) can be formed together on a single substrate to form an array. Such arrays can be employed to form active illuminated displays, such as those employed in, e.g., smartphones and smart watches, computer or video displays, signage, or visualization systems (such as augmented- or virtual-reality displays), or to form adaptive illumination sources, such as those employed in, e.g., automotive headlights, street lighting, camera flash sources, or flashlights (i.e., torches). An array having one or several or many individual devices per millimeter (e.g., device pitch or spacing of about a millimeter, a few hundred microns, less than 100 microns, or even less, and separation between adjacent devices less than 100 microns or only a few microns or even less) typically is referred to as a miniLED array or a microLED array (alternatively, a μLED array). Such miniLED or microLED arrays can be direct-emitting or phosphor-converted (or a mixture of both types).

### SUMMARY

An inventive light-emitting element comprises a semiconductor light-emitting diode, and anode electrical contact, and a cathode electrical contact. The semiconductor LED includes a p-doped semiconductor layer, an n-doped semiconductor layer, and an active, light-emitting layer between them, and is arranged for emitting light at a nominal emission vacuum wavelength λ₀ resulting from radiative recombination of charge carriers at the active layer. The LED has (i) a light-exit surface of the n-doped layer opposite the active layer, (ii) an anode contact surface of the p-doped layer opposite the active layer, and (iii) side surfaces that laterally confine the p-doped layer, the active layer, and the n-doped layer. The p-doped layer has a refractive index of n_{P} and a nonzero thickness less than 10λ₀/n_{P}; the largest transverse dimension of the LED is less than 30λ₀/n_{P}. The cathode electrical contact is electrically coupled to the n-doped layer. The anode electrical contact is directly electrically coupled to the p-doped layer on only a central area of the anode contact surface; the central area is circumscribed by peripheral portions of the anode contact surface that lack direct electrical coupling to the anode electrical contact. Separation between the side surfaces of the LED and lateral edges of the anode electrical contact is greater than λ₀/2n_{P}.

In some examples, transverse dimensions of the LED, separation of the side surfaces and lateral edges of the anode electrical contact, and thickness of the p-doped layer can result in a Purcell factor that is greater than 1.0. In some examples, transverse dimensions of the LED, separation of the side surfaces and lateral edges of the anode electrical contact, and thickness of the p-doped layer can result in extraction efficiency that is greater than 0.3. In some examples, transverse dimensions of the LED, separation of the side surfaces and lateral edges of the anode electrical contact, and thickness of the p-doped layer can result in overall light output efficiency that is greater than 0.5. In some examples, transverse dimensions of the LED, separation of the side surfaces and lateral edges of the anode electrical contact, and thickness of the p-doped layer can result in an angular distribution of output light in which more than 50% of the light output propagates within a cone half-angle that is less than 45° or within a solid angle that is less than 1.8 steradians (sr).

Objects and advantages pertaining to LEDs, pcLEDs, miniLED arrays, pc-miniLED arrays, microLED arrays, and pc-microLED arrays may become apparent upon referring to the examples illustrated in the drawings and disclosed in the following written description or appended claims.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 shows a schematic cross-sectional view of an example LED.

FIGS. 2A and 2B show, respectively, cross-sectional and top schematic views of an example array of LEDs. FIG. 2C shows a top schematic view of another example miniLED or microLED array and an enlarged section of 3×3 LEDs of the array.

FIG. 3A shows a schematic cross-sectional view of an example array of LEDs arranged with respect to waveguides and a projection lens. FIG. 3B shows an arrangement similar to that of FIG. 3A, but without the waveguides.

FIG. 4A shows a schematic top view an example electronics board on which an array of LEDs may be mounted, and FIG. 4B similarly shows an example array of LEDs mounted on the electronic board of FIG. 4A.

FIG. 5A schematically illustrates an example camera flash system. FIG. 5B schematically illustrates an example display system. FIG. 5C shows a block diagram of an example visualization system.

FIGS. 6A-6H are schematic cross-sectional views of several different example light-emitting elements.

FIG. 7 is a schematic cross-sectional view of an array example light-emitting elements.

FIGS. 8A-8C are plots of Purcell factor, extraction efficiency, and overall light output efficiency, respectively, for four different anode contact sizes as a function of thickness of the p-doped layer of an example light-emitting element.

FIG. 9A is a plot of light output intensity versus output angle for the four anode contact sizes of FIGS. 8A-8C and a p-doped layer thickness of 60 nm; FIG. 9B is a plot of relative amounts of output light propagating within a given cone half-angle θₘₐₓ as a function of that cone half-angle, for the four anode contact sizes of FIGS. 8A-8C and a p-doped layer thickness of 60 nm.

FIG. 10A is a plot of light output intensity versus output angle for the four anode contact sizes of FIGS. 8A-8C and a p-doped layer thickness of 170 nm; FIG. 10B is a plot of relative amounts of output light propagating within a given cone half-angle θₘₐₓ as a function of that cone half-angle, for the four anode contact sizes of FIGS. 8A-8C and a p-doped layer thickness of 170 nm.

The examples depicted are shown only schematically; all features may not be shown in full detail or in proper proportion; for clarity certain features or structures may be exaggerated or diminished relative to others or omitted entirely; the drawings should not be regarded as being to scale unless explicitly indicated as being to scale. For example, individual LEDs may be exaggerated in their vertical dimensions or layer thicknesses relative to their lateral extent or relative to substrate or phosphor thicknesses. The examples shown should not be construed as limiting the scope of the present disclosure or appended claims.

### DETAILED DESCRIPTION

The following detailed description should be read with reference to the drawings, in which identical reference numbers refer to like elements throughout the different figures. The drawings, which are not necessarily to scale, depict selective examples and are not intended to limit the scope of the inventive subject matter. The detailed description illustrates by way of example, not by way of limitation, the principles of the inventive subject matter. For purposes of simplicity and clarity, detailed descriptions of well-known devices, circuits, and methods may be omitted so as not to obscure the description of the inventive subject matter with unnecessary detail.

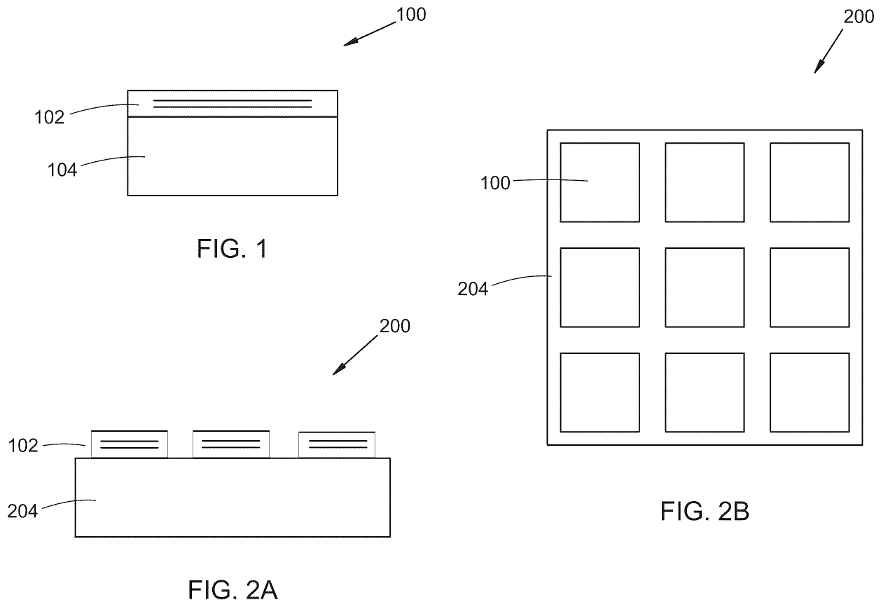

FIG. 1 shows an example of an individual light-emitting diode 100 comprising a semiconductor diode structure 102 disposed on a substrate 104, together considered herein an “LED” or “semiconductor LED”. Semiconductor diode structure 102 typically comprises an active region disposed between n-type and p-type layers. Application of a suitable forward bias across the diode structure 102 results in emission of light from the active region due to radiative recombination of charge carriers. The wavelength of the emitted light is determined by the composition and structure of the active region.

The LED may be, for example, a III-Nitride LED that emits blue, violet, or ultraviolet light. LEDs formed from any other suitable material system and that emit any other suitable wavelength of light may also be used. Other suitable material systems may include, for example, III-Phosphide materials, III-Arsenide materials, other binary, ternary, or quaternary alloys of gallium, aluminum, indium, nitrogen, phosphorus, or arsenic, or II-VI materials.

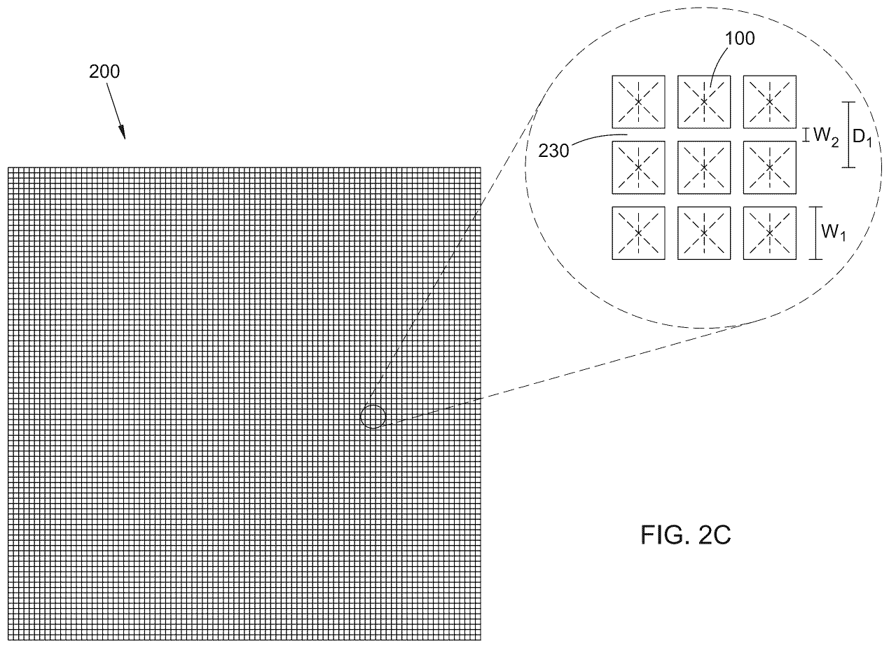

FIGS. 2A and 2B show, respectively, cross-sectional and top views of an array 200 of LEDs 100 disposed on a substrate 204. Such an array can include any suitable number of LEDs arranged in any suitable manner. In the illustrated example the array is depicted as formed monolithically on a shared substrate, but alternatively an array of LEDs can be formed from separate individual LEDs (e.g., singulated devices that are assembled onto an array substrate) or separate groups of multiple LEDs that are assembled together. In segmented monolithic examples individual LEDs can be electrically isolated from each other, e.g., by trenches and or electrically insulating material. In some instances the array 200 can include light barriers (e.g., reflective, scattering, diffusive, and/or absorbing) between adjacent LEDs 102 to provide optical isolation from one another.

Substrate 204 may optionally include electrical traces or interconnects, or CMOS or other circuitry for driving the LEDs, and may be formed from any suitable materials. The individual LEDs (pixels) in an LED array may be individually addressable, may be addressable as part of a group or subset of the pixels in the array, or may not be addressable. Thus, LED arrays can be useful for any application requiring or benefiting from fine-grained intensity, spatial, and temporal control of light distribution. These applications may include, but are not limited to, precise special patterning of emitted light from pixel blocks or individual pixels, in some instances including the formation of images as a display device. Depending on the application, emitted light may be spectrally distinct, adaptive over time, and/or environmentally responsive. The light emitting pixel arrays may provide preprogrammed light distribution in various intensity, spatial, or temporal patterns. The emitted light may be based at least in part on received sensor data and may be used for optical wireless communications. Associated electronics and optics may be distinct at a pixel, pixel block, or device level.

Although FIGS. 2A and 2B show a 3×3 array of nine LEDs, such arrays may include for example on the order of 10¹, 10², 10³, 10⁴, or more LEDs, e.g., as illustrated schematically in FIG. 2C. Individual LEDs 100 (i.e., pixels) may have non-zero widths w₁ (e.g., side lengths or transverse dimensions) in the plane of the array 200, for example, less than or equal to 1 millimeter (mm), less than or equal to 500 microns, less than or equal to 100 microns, less than or equal to 50 microns, less than or equal to 10 microns, or even smaller (as discussed below). LEDs 100 in the array 200 may be spaced apart from each other by streets, lanes, or trenches 230 having a non-zero width w₂ in the plane of the array 200 of, for example, hundreds of microns, less than or equal to 100 microns, less than or equal to 50 microns, less than or equal to 20 microns, less than or equal to 10 microns, less than or equal to 5 microns, or even smaller (as discussed below). The pixel pitch or spacing D₁ is the sum of w₁ and w₂. Although the illustrated examples show identical rectangular LEDs arranged in a symmetric matrix with uniform size, separation, and spacing, the LEDs and the array may have any suitable shape or arrangement, whether symmetric or asymmetric, uniformly or non-uniformly sized, uniformly or non-uniformly spaced, or uniformly or non-uniformly separated. Multiple separate arrays of LEDs can be combined in any suitable arrangement in any applicable format to form a larger combined array or display.

LEDs having dimensions wi in the plane of the array (e.g., side lengths or transverse dimensions) of less than or equal to about 0.10 millimeters microns are typically referred to as microLEDs, and an array of such microLEDs may be referred to as a microLED array. LEDs having dimensions wi in the plane of the array (e.g., side lengths or transverse dimensions) of between about 0.1 millimeters and about 1.0 millimeters are typically referred to as miniLEDs, and an array of such miniLEDs may be referred to as a miniLED array.

Individual LEDs 100 may optionally incorporate or be arranged in combination with a lens or other optical element located adjacent to or disposed on the phosphor layer. Such an optical element, not shown in the figures, may be referred to as a “primary optical element” and may be of any suitable type of arrangement (e.g., conventional refractive or diffractive optical elements, or so-called nanostructured optical elements such as those disclosed in U.S. Pat. No. 11,327,283, U.S. Pub. No. 2020/0343416, U.S. Pub. No. 2020/0335661, U.S. Pub. No. 2021/0184081, U.S. Pub. No. 2022/0146079, or U.S. non-provisional application Ser. No. 17/825,143 filed May 26, 2022, each of which is incorporated by reference in its entirety).

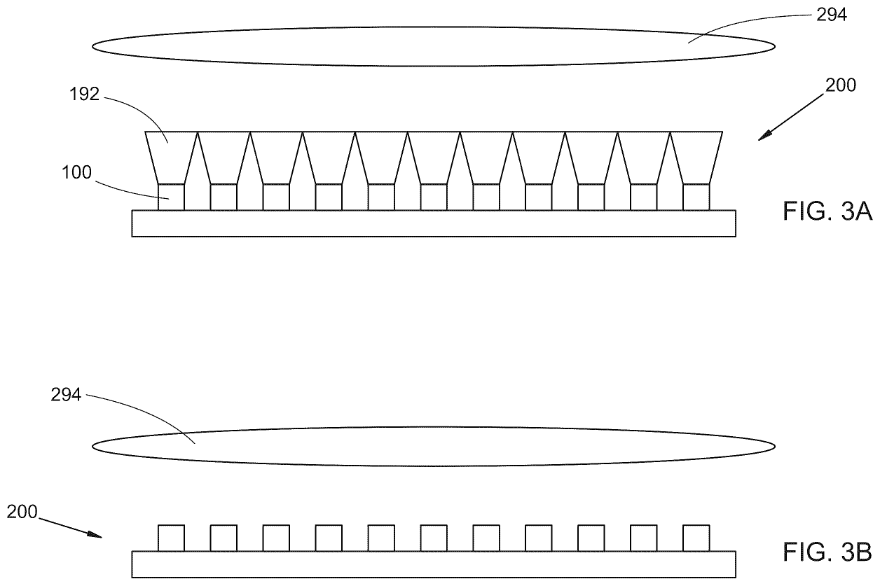

Instead or in addition, as shown in FIGS. 3A and 3B, an LED array 200 (for example, mounted on an electronics board) may be arranged in combination with secondary optical elements such as waveguides, lenses, or both for use in an intended application (for the entire array, for subsets thereof, or for individual pixels; of any suitable type or arrangement, e.g., conventional refractive or diffractive optical elements, or so-called nanostructured optical elements, including any of those listed above). In FIG. 3A, light emitted by each LED 100 of the array 200 is collected by a corresponding waveguide 192 and directed to a projection lens 294. Projection lens 294 may be a Fresnel lens, for example. This arrangement may be suitable for use, for example, in automobile headlights or other adaptive illumination sources. Other primary or secondary optical elements of any suitable type or arrangement can be included for each pixel, as needed or desired. In FIG. 3B, light emitted by LEDs of the array 200 is collected directly by projection lens 294 without use of intervening waveguides. This arrangement may particularly be suitable when LEDs can be spaced sufficiently close to each other, and may also be used in automobile headlights as well as in camera flash applications or other illumination sources. A miniLED or microLED display application may use similar optical arrangements to those depicted in FIGS. 3A and 3B, for example. In another example arrangement, a central block of LEDs in an array can be associated with a single common (shared) optic, while edge LEDs located in the array at the periphery of the central bloc can be each associated with a corresponding individual optic. Generally, any suitable arrangement of optical elements (primary, secondary, or both) can be used in combination with the LEDs described herein, depending on the desired application.

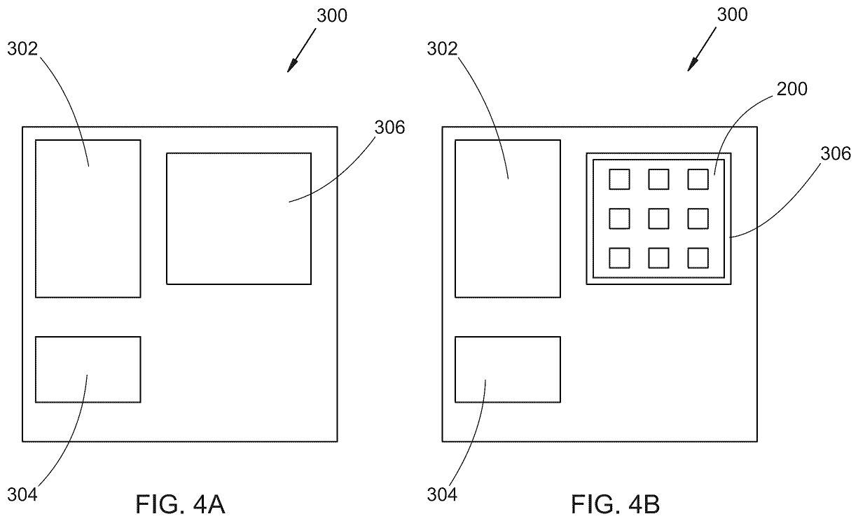

As shown in FIGS. 4A and 4B, a LED array 200 may be mounted on an electronics board 300 comprising a power and control module 302, a sensor module 304, and an LED attach region 306. Power and control module 302 may receive power and control signals from external sources and signals from sensor module 304, based on which power and control module 302 controls operation of the LEDs. Sensor module 304 may receive signals from any suitable sensors, for example from temperature or light sensors. Alternatively, LED array 200 may be mounted on a separate board (not shown) from the power and control module and the sensor module.

An array of independently operable LEDs or pcLEDs may be used in combination with a lens, lens system, or other optic or optical system (e.g., as described above) to provide illumination that is adaptable for a particular purpose. For example, in operation such an adaptive lighting system may provide illumination that varies by color and/or intensity across an illuminated scene or object and/or is aimed in a desired direction. Beam focus or steering of light emitted by the LED or pcLED array can be performed electronically by activating LEDs or pcLEDs in groups of varying size or in sequence, to permit dynamic adjustment of the beam shape and/or direction without moving optics or changing the focus of the lens in the lighting apparatus. A controller can be configured to receive data indicating locations and color characteristics of objects or persons in a scene and based on that information control LEDs or pcLEDs in an array to provide illumination adapted to the scene. Such data can be provided for example by an image sensor, or optical (e.g., laser scanning) or non-optical (e.g., millimeter radar) sensors. Such adaptive illumination is increasingly important for automotive (e.g., adaptive headlights), mobile device camera (e.g., adaptive flash), AR, VR, and MR applications such as those described below.

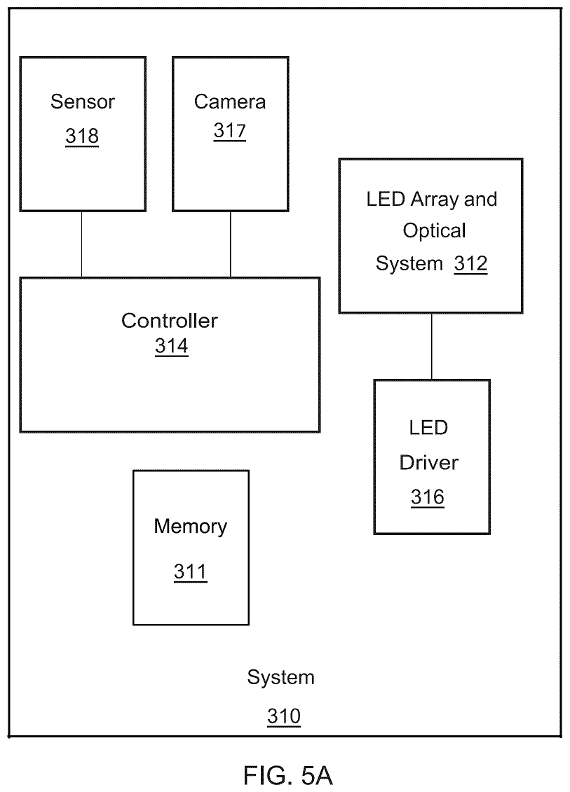

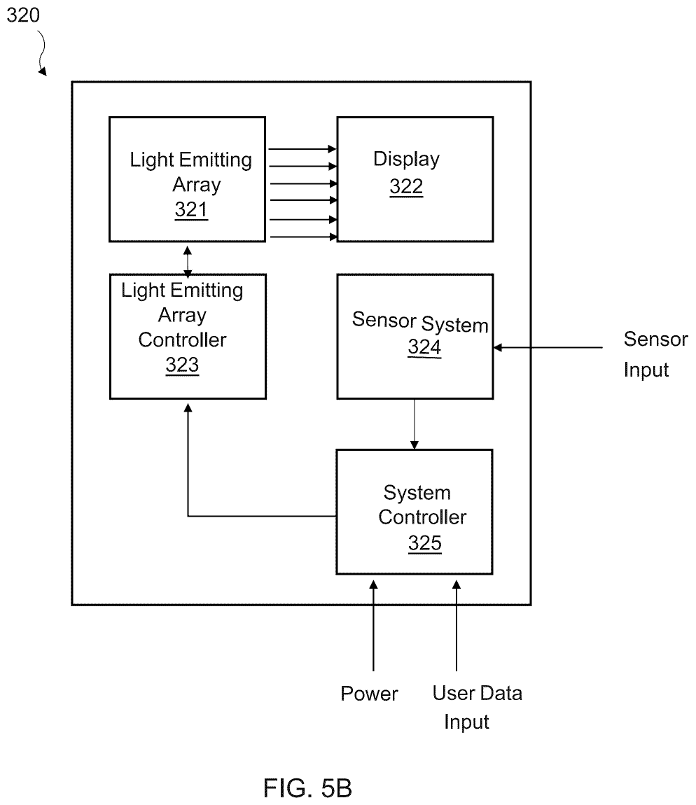

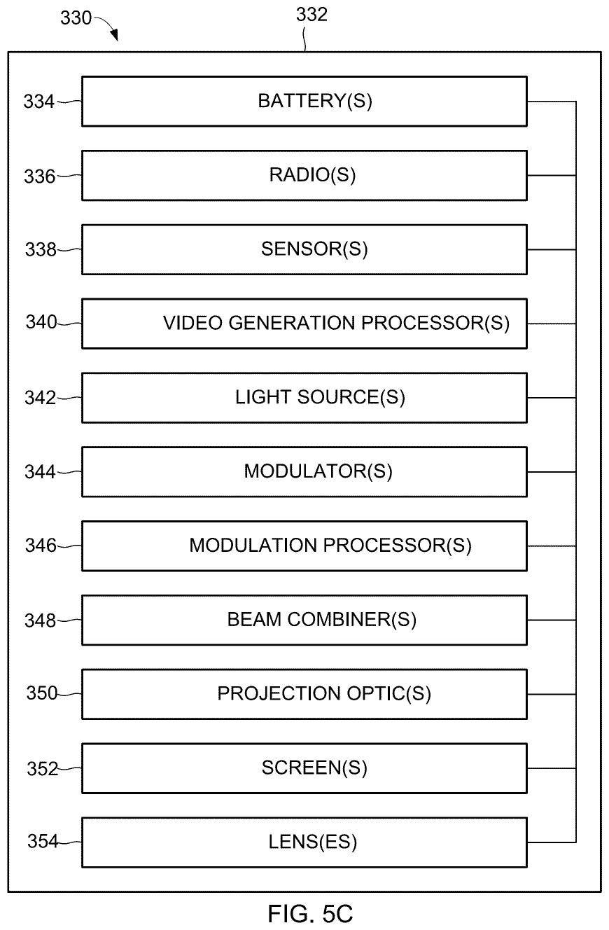

FIG. 5A schematically illustrates an example camera flash system 310 comprising an LED or pcLED array and an optical (e.g., lens) system 312, which may be or comprise an adaptive lighting system as described above in which LEDs or pcLEDs in the array may be individually operable or operable as groups. In operation of the camera flash system, illumination from some or all of the LEDs or pcLEDs in array and optical system 312 may be adjusted—deactivated, operated at full intensity, or operated at an intermediate intensity. The array may be a monolithic array, or comprise one or more monolithic arrays, as described above. The array may be a microLED array, as described above.

Flash system 310 also comprises an LED driver 316 that is controlled by a controller 314, such as a microprocessor. Controller 314 may also be coupled to a camera 317 and to sensors 318 and operate in accordance with instructions and profiles stored in memory 311. Camera 317 and LED or pcLED array and lens system 312 may be controlled by controller 314 to, for example, match the illumination provided by system 312 (i.e., the field of view of the illumination system) to the field of view of camera 317, or to otherwise adapt the illumination provided by system 312 to the scene viewed by the camera as described above. Sensors 318 may include, for example, positional sensors (e.g., a gyroscope and/or accelerometer) and/or other sensors that may be used to determine the position and orientation of system 310.

FIG. 5B schematically illustrates an example display system 320 that includes an array 321 of LEDs or pcLEDs that are individually operable or operable in groups, a display 322, a light emitting array controller 323, a sensor system 324, and a system controller 325. Array 321 may be a monolithic array, or comprise one or more monolithic arrays, as described above. The array may be monochromatic. Alternatively, the array may be a multicolor array in which different LEDs or pcLEDs in the array are configured to emit different colors of light, as described above. The array may therefore be or comprise a monolithic multicolor matrix of individually operable LED or pcLED light emitters, which may for example be microLEDs as described above. A single individually operable LED or pcLED or a group of adjacent such LEDs or pcLEDs in the array may correspond to a single pixel (picture element) in the display. For example, a group of three individually operable adjacent LEDs or pcLEDs comprising a red emitter, a blue emitter, and a green emitter may correspond to a single color-tunable pixel in the display. Similarly, to provide redundancy in the event of a defective LED or pcLED, a group of six individually operable adjacent LEDs or pcLEDs comprising two red emitters, two blue emitters, and two green emitters may correspond to a single color-tunable pixel in the display Array 321 can be used to project light in graphical or object patterns that can for example support AR/VR/MR systems.

Sensor input is provided to the sensor system 324, while power and user data input is provided to the system controller 325. In some embodiments modules included in system 320 can be compactly arranged in a single structure, or one or more elements can be separately mounted and connected via wireless or wired communication. For example, array 321, display 322, and sensor system 324 can be mounted on a headset or glasses, with the light emitting array controller and/or system controller 325 separately mounted.

System 320 can incorporate a wide range of optics (not shown) to couple light emitted by array 321 into display 322. Any suitable optics may be used for this purpose.

Sensor system 324 can include, for example, external sensors such as cameras, depth sensors, or audio sensors that monitor the environment, and internal sensors such as accelerometers or two or three axis gyroscopes that monitor an AR/VR/MR headset position. Other sensors can include but are not limited to air pressure, stress sensors, temperature sensors, or any other suitable sensors needed for local or remote environmental monitoring. In some embodiments, control input through the sensor system can include detected touch or taps, gestural input, or control based on headset or display position.

In response to data from sensor system 324, system controller 325 can send images or instructions to the light emitting array controller 323. Changes or modification to the images or instructions can also be made by user data input, or automated data input as needed. User data input can include but is not limited to that provided by audio instructions, haptic feedback, eye or pupil positioning, or connected keyboard, mouse, or game controller.

As noted above, AR, VR, and MR systems may be more generally referred to as examples of visualization systems. In a virtual reality system, a display can present to a user a view of scene, such as a three-dimensional scene. The user can move within the scene, such as by repositioning the user's head or by walking. The virtual reality system can detect the user's movement and alter the view of the scene to account for the movement. For example, as a user rotates the user's head, the system can present views of the scene that vary in view directions to match the user's gaze. In this manner, the virtual reality system can simulate a user's presence in the three-dimensional scene. Further, a virtual reality system can receive tactile sensory input, such as from wearable position sensors, and can optionally provide tactile feedback to the user.

In an augmented reality system, the display can incorporate elements from the user's surroundings into the view of the scene. For example, the augmented reality system can add textual captions and/or visual elements to a view of the user's surroundings. For example, a retailer can use an augmented reality system to show a user what a piece of furniture would look like in a room of the user's home, by incorporating a visualization of the piece of furniture over a captured image of the user's surroundings. As the user moves around the user's room, the visualization accounts for the user's motion and alters the visualization of the furniture in a manner consistent with the motion. For example, the augmented reality system can position a virtual chair in a room. The user can stand in the room on a front side of the virtual chair location to view the front side of the chair. The user can move in the room to an area behind the virtual chair location to view a back side of the chair. In this manner, the augmented reality system can add elements to a dynamic view of the user's surroundings.

FIG. 5C shows a generalized block diagram of an example visualization system 330. The visualization system 330 can include a wearable housing 332, such as a headset or goggles. The housing 332 can mechanically support and house the elements detailed below. In some examples, one or more of the elements detailed below can be included in one or more additional housings that can be separate from the wearable housing 332 and couplable to the wearable housing 332 wirelessly and/or via a wired connection. For example, a separate housing can reduce the weight of wearable goggles, such as by including batteries, radios, and other elements. The housing 332 can include one or more batteries 334, which can electrically power any or all of the elements detailed below. The housing 332 can include circuitry that can electrically couple to an external power supply, such as a wall outlet, to recharge the batteries 334. The housing 332 can include one or more radios 336 to communicate wirelessly with a server or network via a suitable protocol, such as WiFi.

The visualization system 330 can include one or more sensors 338, such as optical sensors, audio sensors, tactile sensors, thermal sensors, gyroscopic sensors, time-of-flight sensors, triangulation-based sensors, and others. In some examples, one or more of the sensors can sense a location, a position, and/or an orientation of a user. In some examples, one or more of the sensors 338 can produce a sensor signal in response to the sensed location, position, and/or orientation. The sensor signal can include sensor data that corresponds to a sensed location, position, and/or orientation. For example, the sensor data can include a depth map of the surroundings. In some examples, such as for an augmented reality system, one or more of the sensors 338 can capture a real-time video image of the surroundings proximate a user.

The visualization system 330 can include one or more video generation processors 340. The one or more video generation processors 340 can receive, from a server and/or a storage medium, scene data that represents a three-dimensional scene, such as a set of position coordinates for objects in the scene or a depth map of the scene. The one or more video generation processors 340 can receive one or more sensor signals from the one or more sensors 338. In response to the scene data, which represents the surroundings, and at least one sensor signal, which represents the location and/or orientation of the user with respect to the surroundings, the one or more video generation processors 340 can generate at least one video signal that corresponds to a view of the scene. In some examples, the one or more video generation processors 340 can generate two video signals, one for each eye of the user, that represent a view of the scene from a point of view of the left eye and the right eye of the user, respectively. In some examples, the one or more video generation processors 340 can generate more than two video signals and combine the video signals to provide one video signal for both eyes, two video signals for the two eyes, or other combinations.

The visualization system 330 can include one or more light sources 342 that can provide light for a display of the visualization system 330. Suitable light sources 342 can include any of the LEDs, pcLEDs, LED arrays, and pcLED arrays discussed above, for example those discussed above with respect to display system 320.

The visualization system 330 can include one or more modulators 344. The modulators 344 can be implemented in one of at least two configurations.

In a first configuration, the modulators 344 can include circuitry that can modulate the light sources 342 directly. For example, the light sources 342 can include an array of light-emitting diodes, and the modulators 344 can directly modulate the electrical power, electrical voltage, and/or electrical current directed to each light-emitting diode in the array to form modulated light. The modulation can be performed in an analog manner and/or a digital manner. In some examples, the light sources 342 can include an array of red light-emitting diodes, an array of green light-emitting diodes, and an array of blue light-emitting diodes, and the modulators 344 can directly modulate the red light-emitting diodes, the green light-emitting diodes, and the blue light-emitting diodes to form the modulated light to produce a specified image.

In a second configuration, the modulators 344 can include a modulation panel, such as a liquid crystal panel. The light sources 342 can produce uniform illumination, or nearly uniform illumination, to illuminate the modulation panel. The modulation panel can include pixels. Each pixel can selectively attenuate a respective portion of the modulation panel area in response to an electrical modulation signal to form the modulated light. In some examples, the modulators 344 can include multiple modulation panels that can modulate different colors of light. For example, the modulators 344 can include a red modulation panel that can attenuate red light from a red light source such as a red light-emitting diode, a green modulation panel that can attenuate green light from a green light source such as a green light-emitting diode, and a blue modulation panel that can attenuate blue light from a blue light source such as a blue light-emitting diode.

In some examples of the second configuration, the modulators 344 can receive uniform white light or nearly uniform white light from a white light source, such as a white-light light-emitting diode. The modulation panel can include wavelength-selective filters on each pixel of the modulation panel. The panel pixels can be arranged in groups (such as groups of three or four), where each group can form a pixel of a color image. For example, each group can include a panel pixel with a red color filter, a panel pixel with a green color filter, and a panel pixel with a blue color filter. Other suitable configurations can also be used.

The visualization system 330 can include one or more modulation processors 346, which can receive a video signal, such as from the one or more video generation processors 340, and, in response, can produce an electrical modulation signal. For configurations in which the modulators 344 directly modulate the light sources 342, the electrical modulation signal can drive the light sources 344. For configurations in which the modulators 344 include a modulation panel, the electrical modulation signal can drive the modulation panel.

The visualization system 330 can include one or more beam combiners 348 (also known as beam splitters 348), which can combine light beams of different colors to form a single multi-color beam. For configurations in which the light sources 342 can include multiple light-emitting diodes of different colors, the visualization system 330 can include one or more wavelength-sensitive (e.g., dichroic) beam splitters 348 that can combine the light of different colors to form a single multi-color beam.

The visualization system 330 can direct the modulated light toward the eyes of the viewer in one of at least two configurations. In a first configuration, the visualization system 330 can function as a projector, and can include suitable projection optics 350 that can project the modulated light onto one or more screens 352. The screens 352 can be located a suitable distance from an eye of the user. The visualization system 330 can optionally include one or more lenses 354 that can locate a virtual image of a screen 352 at a suitable distance from the eye, such as a close-focus distance, such as 500 mm, 750 mm, or another suitable distance. In some examples, the visualization system 330 can include a single screen 352, such that the modulated light can be directed toward both eyes of the user. In some examples, the visualization system 330 can include two screens 352, such that the modulated light from each screen 352 can be directed toward a respective eye of the user. In some examples, the visualization system 330 can include more than two screens 352. In a second configuration, the visualization system 330 can direct the modulated light directly into one or both eyes of a viewer. For example, the projection optics 350 can form an image on a retina of an eye of the user, or an image on each retina of the two eyes of the user.

For some configurations of augmented reality systems, the visualization system 330 can include an at least partially transparent display, such that a user can view the user's surroundings through the display. For such configurations, the augmented reality system can produce modulated light that corresponds to the augmentation of the surroundings, rather than the surroundings itself. For example, in the example of a retailer showing a chair, the augmented reality system can direct modulated light, corresponding to the chair but not the rest of the room, toward a screen or toward an eye of a user.

For purposes of the present disclosure and appended claims, any arrangement of a layer, surface, substrate, diode structure, or other structure “on,” “over,” or “against” another such structure shall encompass arrangements with direct contact between the two structures as well as arrangements including some intervening structure between them. Conversely, any arrangement of a layer, surface, substrate, diode structure, or other structure “directly on,” “directly over,” or “directly against” another such structure shall encompass only arrangements with direct contact between the two structures. For purposes of the present disclosure and appended claims, a layer, structure, or material described as “transparent” or “substantially transparent” shall exhibit, at the nominal emission vacuum wavelength λ₀, a level of optical transmission that is sufficiently high, or a level of optical loss (due to absorption, scattering, or other loss mechanism) that is sufficiently low, that the light-emitting device can function within operationally acceptable parameters (e.g., output power or luminance, conversion or extraction efficiency, or other figures-of-merit including those described below).

A semiconductor LED produces light when charge carriers radiatively recombine in an active layer between n-doped and p-doped semiconductor layers. Charge carriers are introduced into the LED as electrical drive current. An important parameter characterizing an LED is the overall light output efficiency, i.e., the number of photons emitted from a light output surface of the LED divided by the number of charge carriers introduced into the LED as drive current. Also important is the angular distribution of that output light, with a narrower angular distribution generally being considered more desirable than a wider angular distribution (e.g., to enable more intense or focused illumination, or to reduce stray light). Much research and development effort has been and continues to be expended to improve the overall efficiency and/or angular light distribution of LEDs. Such improvements can include but are not limited to one or more of increasing the internal quantum efficiency of the LED, altering the angular distribution light within the LED or exiting the LED, or increasing the extraction efficiency of the LED. The internal quantum efficiency (IQE) is the fraction of charge carriers that produce photons in the active layer; IQE is sometimes parameterized as the Purcell factor. Extraction efficiency (ExE) is the fraction of photons produced in the active layer that escape the LED through its light output surface. The overall light output efficiency is a product of IQE and ExE.

Previous efforts to increase IQE (i.e., to increase the Purcell factor) have included alteration of the structure or composition of the active layer (e.g., p-n junction, quantum wells, multi-quantum wells, and so forth), or alteration of the structure of the LED near the active layer (e.g., thickness of the p-doped layer between the active layer and an anode electrical contact or a reflector, structure of a backside reflector, or placement and arrangement of one or more nanostructured layers near the active layer). A few examples of such arrangements are disclosed in, e.g., U.S. Pat. No. 11,268,676 issued Mar. 8, 2022, U.S. Pub. No. 2021/0184081 published Jun. 17, 2021, or U.S. non-provisional application Ser. Nos. 17/701,319 filed Mar. 22, 2022, 17/879,948 filed Aug. 3, 2022, 17/880,863 filed Aug. 4, 2022, or 17/880,976 filed Aug. 4, 2022, each of which is incorporated by reference in its entirety. In addition to increasing the Purcell factor, those alterations of the LED structure can also result in an angular distribution of light produced in the active layer that is preferentially directed toward the light output surface (e.g., within the escape cone of the light output surface) instead of laterally within the LED. Such a preferentially directed angular distribution can result in improved extraction efficiency, because a smaller fraction of the light produced in the active layer is internally reflected at the light output surface. Extraction efficiency also can be improved by alterations of the light output surface, such as grooves, corrugations, roughening, scattering elements, an anti-reflection layers, or one or more nanostructured layers. Examples are disclosed in one or more of the reference incorporated above.

Previous efforts have been directed to narrow the output light angular distribution (i.e., the angular distribution of light exiting the LED through a light-exit surface thereof). Some of the structural adaptations disclosed in the references incorporated above have been employed to achieve a narrowed output light angular distribution (e.g., narrower than a Lambertian distribution). In some examples, directing a larger fraction of light emitted by the active layer to propagate within the LED within its escape cone can result in a narrowed angular distribution of output light. In some examples, non-refractive transmissive redirection (i.e., that does not obey Snell's Law) can be effected at the light-exit surface by a suitably arranged nanostructured layer.

As in many other technological areas (microprocessors, semiconductor lasers, and so forth), there has been ongoing development of ever smaller LED-based devices. However, as transverse dimensions of the LED shrink to sizes just a few times larger than the wavelength of the light emitted by the LED (referred to herein as a micron-scale LED), some of the structural alterations described above become unfeasible to implement. In some examples, corrugations or scattering elements typically are much larger than the wavelength of the LED output light. In other examples, nanostructured layers operate by the collective action of a multitude of nanostructured elements with spacings on the order of the wavelength of the output light or smaller. If the largest transverse dimension of the LED is only a few times larger than the wavelength, there is insufficient space for enough nanostructured elements in such a nanostructured layer.

It would be desirable to provide an LED with transverse dimensions only a few times larger than the output wavelength that nevertheless can exhibit one or more of an improved Purcell factor, an improved extraction efficiency, or a narrowed output angular distribution (e.g., narrower than a Lambertian distribution).

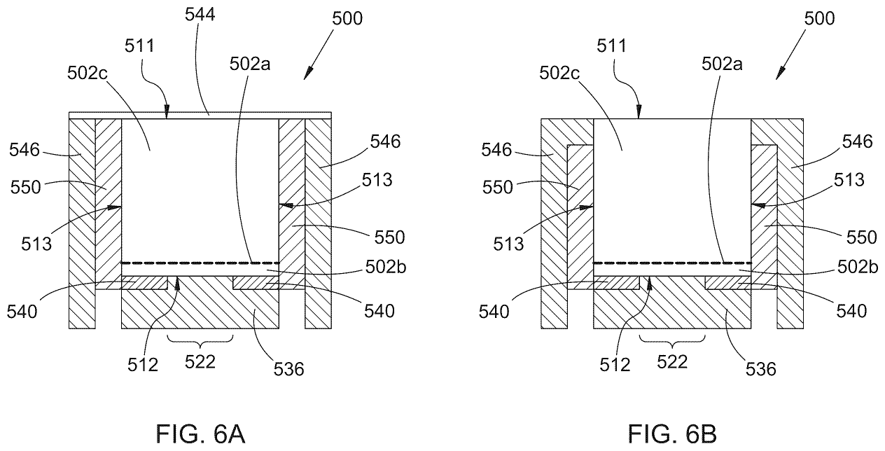

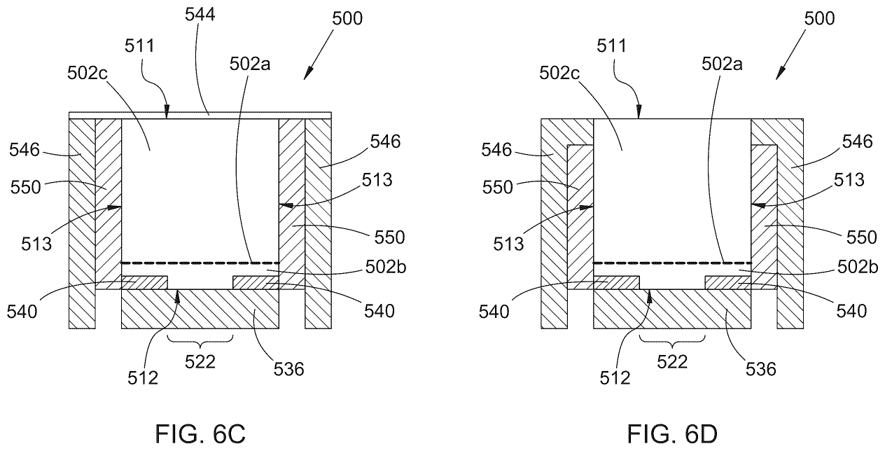

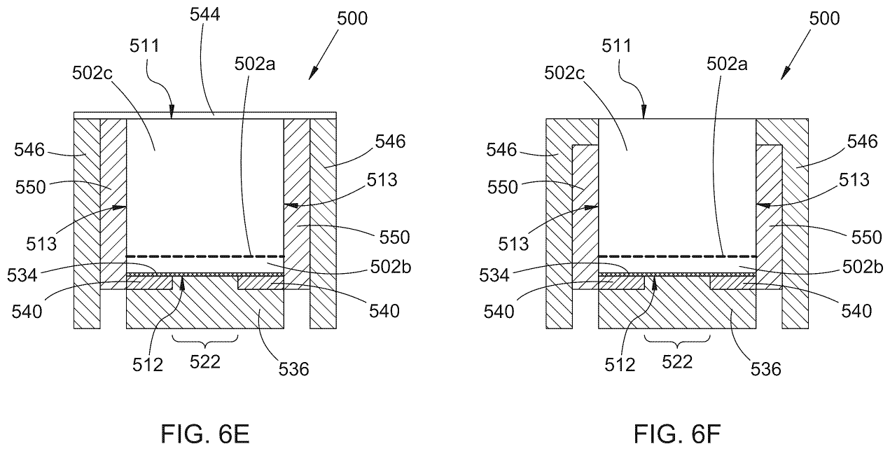

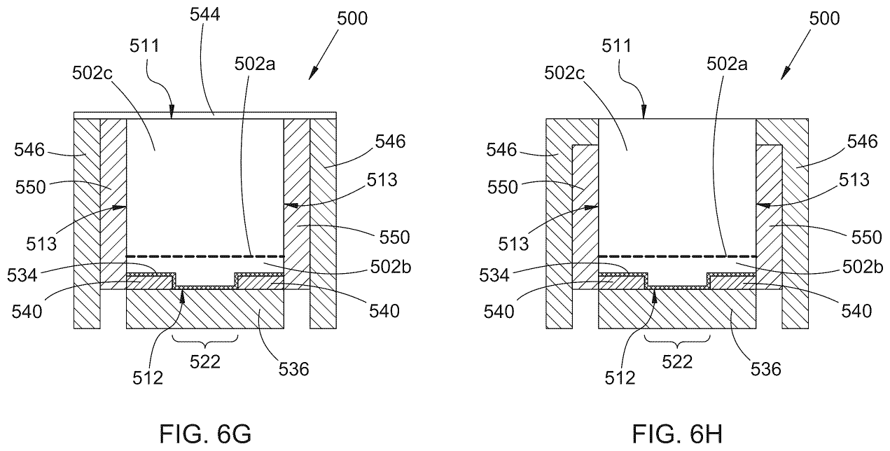

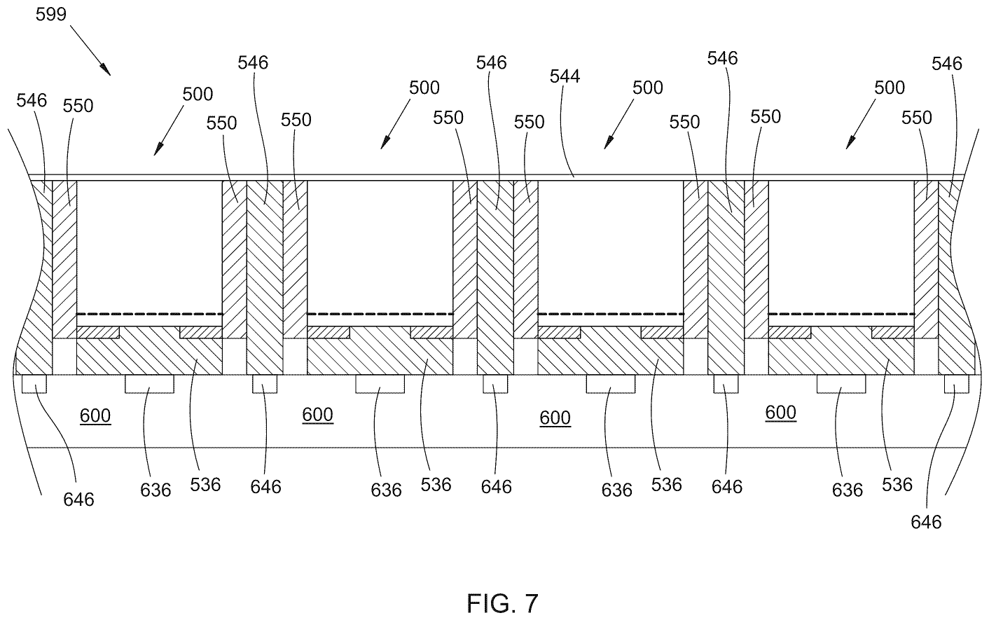

Various examples of an inventive light-emitting element 500 are illustrated schematically in cross-section in FIGS. 6A-6H. A schematic cross-section of an array 599 of multiple light-emitting elements 500 of FIG. 6A is shown in FIG. 7; similar arrays can be formed using multiple light-emitting elements 500 of any one of FIGS. 6B-6H. The light-emitting element 500 includes a semiconductor light-emitting diode (LED) with anode and cathode electrical contacts. The semiconductor LED includes a p-doped semiconductor layer 502b, an n-doped semiconductor layer 502c, and an active, light-emitting layer 502a between the p-doped and n-doped layers 502b/502c. The LED emits light at a nominal emission vacuum wavelength λ₀ resulting from radiative recombination of charge carriers at the active layer 502a. The LED has (i) a light-exit surface 511 of the n-doped layer 502c opposite the active layer 502a, (ii) an anode contact surface 512 of the p-doped layer 502b opposite the active layer 502a, and (iii) one or more side surfaces 513 that laterally confine the p-doped layer 502b, the active layer 502a, and the n-doped layer 502c. The p-doped layer has a refractive index of n_{P} and a nonzero thickness less than 10λ₀/n_{P} (but sufficiently thick for the LED to function as an LED, e.g., in some examples greater than λ₀/10n_{P}). The largest transverse dimension of the LED is less than 30λ₀/n_{P}, while the smallest transverse dimension of the LED is nonzero and sufficiently large for the LED to function as an LED, e.g., in some examples greater than λ₀/n_{P}. The active layer 502a typically extends to the side surfaces 513. In some examples the side surfaces 513 laterally confine the entire n-doped layer 502c (e.g., as in FIGS. 6A-6D and 7). In some examples (not shown) the side surfaces 513 laterally confine only a portion of the n-doped layer 502c; in such examples a top portion of the n-doped layer can be contiguous across multiple light-emitting elements 500 arranged in an array.

In some examples, the LED, including any one or more of its constituent layers 502a/502b/502c, can include one or more doped or undoped III-V, II-VI, or Group IV semiconductor materials or alloys or mixtures thereof. In some examples, the active layer 502a can include one or more p-n junctions, one or more quantum wells, one or more multi-quantum wells, or one or more quantum dots. In some examples the nominal emission vacuum wavelength λ₀ can be greater than 0.2 μm, greater than 0.4 μm, greater than 0.8 μm, less than 10 μm, less than 3 μm, or less than 1 μm. In some examples the total nonzero thickness of the layers 502a/502b/502c of the LED can be less than 10 μm, less than 5 μm, less than 3 μm, less than 2 μm, less than 1.5 μm, or less than 1.0 μm (but still large enough for the layers 502a/502b/502c to function collectively as an LED). In some examples the light-emitting device can be arranged and used as a so-called direct emitter, wherein the output light includes light at only the wavelength λ₀. In other examples the light-emitting element 500 can include a wavelength-converting structure (not shown) of any suitable type or arrangement (e.g., a phosphor). The wavelength-converting structure can be positioned in a path of output light exiting the light-exit surface 511 and arranged to absorb at least a portion of the output light at the wavelength λ₀ and to emit light at one or more vacuum wavelengths that are each longer than λ₀.

The cathode electrical contact is electrically coupled to the n-doped layer 502c. The anode electrical contact is directly electrically coupled to the p-doped layer 502b on only a central area 522 of the anode contact surface 512. The central area 522 is circumscribed by peripheral portions of the anode contact surface 512 that lack direct electrical coupling to the anode electrical contact to form a reduced-area central anode contact. Separation between the side surfaces 513 and lateral edges of the anode electrical contact are greater than λ₀/2n_{P}. “Directly electrically coupled” designates those areas of the anode contact surface 512 where electrical current flows between the p-doped layer 502b and the anode electrical contact. Other portions of the anode contact surface 512 that “lack direct electrical coupling” are separated or insulated from the anode electrical contact so that current does not flow through those areas of the anode contact surface 512. Those corresponding portions of the p-doped layer 502b that lack direct electrical coupling to the anode electrical contact can still be indirectly electrically coupled to the anode electrical contact, e.g., by lateral movement of charge carriers through the p-doped layer 502b or the active layer 502a.

Note that although the plural is used throughout for “side surfaces”, “side walls”. “lateral edges”, and so forth, those terms shall also encompass curved geometries wherein there may not be a clear demarcation between multiple distinct “side surfaces”, “side walls”, or “lateral edges”. For example, the lateral surface of a cylindrical LED is referred to herein as its “side surfaces”, and the perimeter of a circular central region 522 is referred to herein as its “lateral edges”.

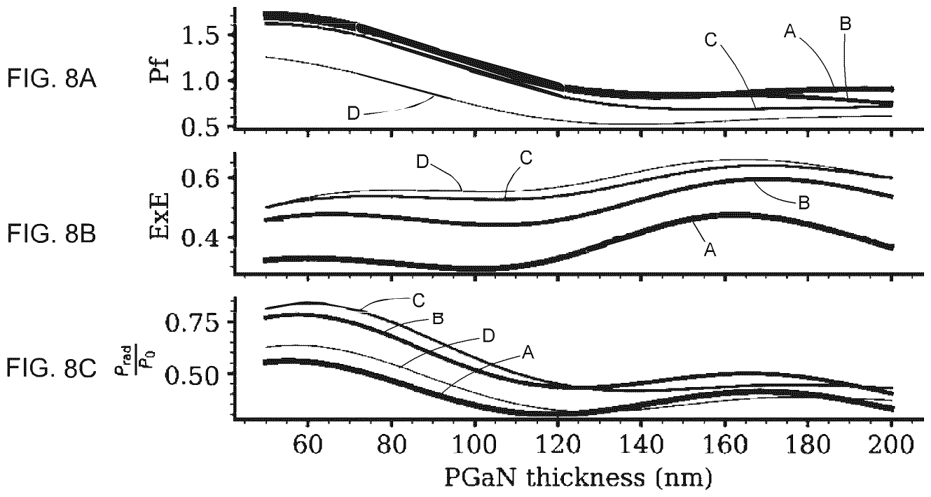

As noted above, for micron-scale LEDs many of the structural adaptations or arrangements employed for improving efficiency or directionality of the LED light output cannot be readily implemented due to size constraints. However, the separation between the lateral edges of the central region 522 and the side surfaces 513, and the thickness of the p-doped layer 502b, are structural parameters of the light-emitting element 500 that can be manipulated for altering or improving the efficiency or directionality of light output from such micron-scale LEDs. FIGS. 8A-8C, 9A, 9B, 10A, and 10B show simulation data for a light-emitting element 500 having a circular transverse cross section with a radius of 500 nm (i.e., a largest transverse dimension of 1 μm, or about 7.5λ₀/n_{P} for an example GaN-based LED emitting at λ₀=400 nm). Calculations were performed for circular central regions 522 of the anode contact surface 512 with radii of 100 nm, 200 nm, 300 nm, and 500 nm (corresponding to curves D, C, B, and A, respectively, in FIGS. 8A through 10B). The largest of those central regions (radius 500 nm) fills the entire anode contact surface 512 (i.e., zero or negligible separation between the central region 522 and the side surface 513) and serves as a control. The central regions 522 with radii of 100 nm, 200 nm, and 300 nm form reduced-area central anode contacts with corresponding separations between the central region 522 and the side surface 513 of 3λ₀/n_{P}, 2.25λ₀/n_{P}, and 1.5λ₀/n_{P}, respectively, for the example GaN-based LED emitting at λ₀=400 nm. In those examples current flows between the p-doped layer 502b and the anode electrical contact only in those reduced-area central regions 522, and the relatively thin p-doped layer 502b means that light emitted from the active layer 502a may preferentially emanate from a roughly corresponding reduced-area central region of the active layer 502a.

FIGS. 8A-8C are plots of Purcell factor, extraction efficiency, and overall light output efficiency, respectively, for the four different anode contact sizes as a function of thickness of the p-doped layer 502b from 50 nm to 200 nm (i.e., from 0.375λ₀/n_{P} to 1.5λ₀/n_{P} for the example GaN-based LED emitting at λ₀=400 nm). FIG. 8A shows that the Purcell factor is similar for the three largest anode contacts (curves A, B, and C), but drops off for the smallest (curve D). For all of the anode contact sizes, the Purcell factor decreases with increasing thickness of the p-doped layer up to about λ₀/n_{P} and then remains fairly constant as the thickness of the p-doped layer increases further. FIG. 8B shows that the extraction efficiency increases for all four electrodes above λ₀/n_{P}, and increases with decreasing size of the anode contact. The net effect of those variations is shown in FIG. 8C, which shows plots of overall light output efficiency. The largest overall efficiency (about 85%) occurs at a p-doped layer thickness of about λ₀/2n_{P} for the anode contact having a radius of 200 nm (curve C). The anode contact having a radius of 300 nm (curve B) exhibits a maximum overall efficiency of nearly 80%. The largest and smallest anode contacts (curves A and D, respectively) exhibit significantly lower overall efficiencies of about 55% to 65%. The simulation results depicted in FIGS. 8A-8C demonstrate that reducing the thickness of the p-doped layer 502b and reducing the area of the central anode contact (i.e., the area of the central region 522) can result in improved overall light output efficiency relative to a thicker p-doped layer 502b and an anode contact that occupies the entire area of the anode contact surface 512.

In some examples the transverse dimensions of the LED, the separation of the side surfaces 513 and lateral edges of the anode electrical contact, and the thickness of the p-doped layer 502b can result in a Purcell factor that is greater than 1.0, greater than 1.1, greater than 1.2, greater than 1.3, greater than 1.4, greater than 1.5, greater than 1.6, or greater than 1.7. In some examples the transverse dimensions of the LED, the separation between the side surfaces 513 and lateral edges of the anode electrical contact, and the thickness of the p-doped layer 502b can result in extraction efficiency that is greater than 0.3, greater than 0.4, greater than 0.5, greater than 0.6, greater than 0.7, or greater than 0.8. In some examples the transverse dimensions of the LED, the separation between the side surfaces 513 and lateral edges of the anode electrical contact, and the thickness of the p-doped layer 502b can result in overall light output efficiency that is greater than 0.5, greater than 0.6, greater than 0.7, or greater than 0.8.

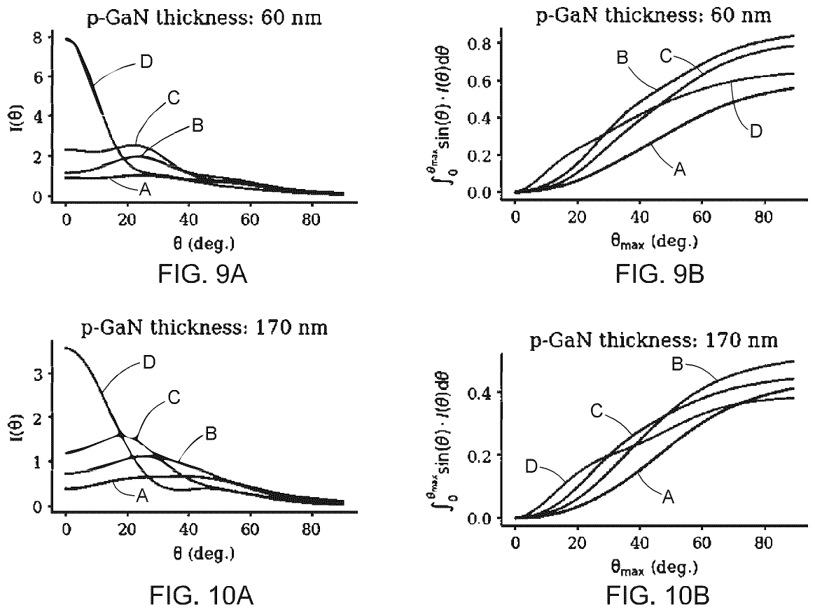

FIGS. 9A and 10A are plots of light output intensity versus output angle (with respect to a direction normal to the light-exit surface 511) for the same set of four anode contact sizes described above and for p-doped layer thicknesses of 60 nm and 170 nm (i.e., λ₀/2n_{P} for the λ₀/2n_{P} for the), respectively. For those same arrangements, FIGS. 9B and 10B are plots of relative amounts of output light propagating within a given cone half-angle θₘₐₓ as a function of that cone half-angle. The cone half-angle is defined herein as the angle between the cone axis and frustum. For both p-doped layer thicknesses, the smallest anode contact size (radius of 100 nm; curve D) yields the highest on-axis (θ=0°) intensity and the smallest cone half-angle (about 30°) within which 50% of the output light propagates. The largest anode contact area (radius=500 nm, occupying the entire anode contact surface 512; curve A) yields the lowest on-axis intensity and widest cone half-angles (about 45°-50°, roughly comparable to a Lambertian angular distribution). The two intermediate anode contact sizes (radii of 200 nm or 300 nm; curves C and B, respectively) yield intermediate on-axis intensities and intermediate cone half-angles.

In some examples the transverse dimensions of the LED, the separation between the side surfaces 513 and the lateral edges of the anode electrical contact, and the thickness of the p-doped layer 502b can result in an angular distribution of output light in which more than 50% of the output light propagates within a cone half-angle that is less than 60°, less than 45°, less than 40°, less than 35°, or less than 30°. More generally, for arrangements lacking rotational symmetry, the transverse dimensions of the LED, the separation between the side surfaces 513 and the lateral edges of the anode electrical contact, and the thickness of the p-doped layer 502b can result in an angular distribution of output light in which more than 50% of the output light propagates within a solid angle that is less than about 3 steradians (i.e., 3 sr; e.g., within a cone defined by a half-angle of about 60°), less than about 1.8 sr (e.g., within a cone defined by a half-angle of about 45°), less than about 1.5 sr (e.g., within a cone defined by a half-angle of about 40°), less than about 1.2 sr (e.g., within a cone defined by a half-angle of about 36°), less than about 1.0 sr (e.g., within a cone defined by a half-angle of about 33°), or less than about 0.8 sr (e.g., within a cone defined by a half-angle of about 29°).

In some examples the largest transverse dimension of the LED can be less than 30λ₀/n_{P}, less than 20λ₀/n_{P}, less than 10λ₀/n_{P}, less than 5λ₀/n_{P}, less than 3λ₀/n_{P}, or less than 2λ₀/n_{P}. In some examples the largest transverse dimension of the LED can be less than 10 μm, less than 5 μm, less than 3 μm, less than 2 μm, or less than 1 μm. In some examples the separation between the side surfaces 513 and lateral edges of the anode electrical contact can be greater than λ₀/2n_{P}, greater than λ₀/n_{P}, greater than 2λ₀/n_{P}, greater than 3λ₀/n_{P}, greater than 5λ₀/n_{P}, or greater than 10λ₀/n_{P}. In some examples the separation between lateral edges of the anode electrical contact and the side surfaces 513 can be greater than 0.02 μm, greater than 0.05 μm, greater than 0.1 μm, greater than 0.2 μm, greater than 0.3 μm, greater than 0.5 μm, or greater than 1 μm. In some examples the central area 522 can occupy a non-zero fraction of total area of the anode contact surface 512 of the p-doped layer 502b that is less than 70%, less than 50%, less than 40%, less than 30%, less than 20%, or less than 10% (while still being large enough for the anode contact to function as a contact). In some examples the nonzero thickness of the p-doped layer 502b can be less than 10λ₀/n_{P}, less than 5λ₀/n_{P}, less than 3λ₀/n_{P}, less than 2λ₀/n_{P}, less than λ₀/n_{P}, less than λ₀/2n_{P}, less than λ₀/3n_{P}, or less than λ₀/5n_{P}. In some examples the nonzero thickness of the p-doped layer 502b can be less than 1.5 μm, less than 1.0 μm, less than 0.5 μm, less than 0.3 μm, less than 0.2 μm, less than 0.1 μm, less than 0.05 μm, or less than 0.04 μm, less than 0.03 μm, or less than 0.02 μm.

In some examples the LED includes side surfaces 513 that are substantially flat and substantially perpendicular to the light-exit surface 511 and the anode contact surface 512. In some of those examples the side surfaces 513 can be flat in two dimensions, e.g., as side facets of a square or rectangular element 500; in some of those examples the side surfaces 513 can be flat in only the vertical dimension, e.g., as the side surface of a cylindrical LED. In some examples (not shown) the side surfaces 513 can form acute or obtuse internal angles with one or both of the light-exit surface 511 or the anode contact surface 512.

In some examples the light-emitting element 500 can include an electrically insulating back dielectric layer 540 on the peripheral portions of the anode contact surface 512 that lack direct electrical coupling to the anode electrical contact. In some examples the back dielectric layer 540 can comprise material of the p-doped layer 502b that is oxidized or passivated; in some other examples the back dielectric layer 540 can comprise material (e.g., silicon oxide) different from material of the p-doped layer 502b and different from oxidized or passivated material of that layer. In some examples (e.g., as in FIGS. 6A, 6B, 6E, and 6F) material of the anode electrical contact can extend through the back dielectric layer 540 and be directly electrically coupled to the central area 522 of the anode contact surface 512; in some other examples (e.g., FIGS. 6C, 6D, 6G, and 6H) non-oxidized and non-passivated material of the p-doped layer 502b can extend through the back dielectric layer 540 to form the central area 522 of the anode contact surface 512 directly electrically coupled to the anode electrical contact. In any of those examples and in some other examples, the back dielectric layer 540 can include one or more materials among: doped or undoped silicon oxide, nitride, or oxynitride; one or more doped or undoped semiconductor oxides, nitrides, or oxynitrides; one or more doped or undoped metal oxides, nitrides, or oxynitrides; one or more optical glasses; or one or more doped or undoped polymers. In some examples the back dielectric layer 540 can include only a single layer of a single dielectric material; in other examples the back dielectric layer 540 can include multiple layers or multiple materials.

In some examples the anode electrical contact can comprise a metal layer in direct contact with the central area 522 of the anode contact surface 512. Such a metal layer can include one or more of aluminum, silver, gold, or other metal or metallic alloy. In some examples the light-emitting element 500 can include an electrically conductive anode bonding layer 536 that is (i) electrically coupled to the central region 522 of the anode contact surface 512 by the anode electrical contact and (ii) electrically isolated from the active and n-doped layers 502a/502c. Such an anode bonding layer 536 can include one or more of aluminum, silver, gold, or other metal or metallic alloy. In some examples (e.g., as in FIGS. 6A-6D), the anode electrical contact can be a portion of the anode bonding layer 536 in direct contact with the central area 522 of the anode contact surface 512. In some other examples (e.g., as in FIGS. 6E-6H) a distinct anode contact layer can electrically couple the anode bonding layer 536 to the central region 522 of the anode contact surface 512 of the p-doped layer 502b (e.g., a transparent conductive oxide (TCO) layer 534 as in FIGS. 6E-6H, or a metal layer (not shown) of any suitable type or composition). A TCO layer 534 (if present) can have a nonzero thickness less than 20 nm (but still thick enough to establish or enhance electrical contact with the p-doped layer 502b); such a thin layer can result in current flow remaining localized to the central region 522.

In some examples the light-emitting element 500 can include an electrically insulating lateral dielectric layer 550 on at least portions of the side surfaces 513. The lateral dielectric layer 550 can circumscribe (i.e., surround in two dimensions) sidewalls of the p-doped layer 502b, sidewalls of the active layer 502a, and at least a portion of sidewalls of the n-doped layer 502c. In some examples the lateral dielectric layer 550 can include one or more materials among: doped or undoped silicon oxide, nitride, or oxynitride; one or more doped or undoped semiconductor oxides, nitrides, or oxynitrides; one or more doped or undoped metal oxides, nitrides, or oxynitrides; one or more optical glasses; or one or more doped or undoped polymers. In some examples the lateral dielectric layer 550 can include only a single layer of a single dielectric material; in other examples the lateral dielectric layer 550 can include multiple layers or multiple materials. In some examples the lateral dielectric layer 550 can be contiguous with the back dielectric layer 540. In some examples the back dielectric layer 540 and the lateral dielectric layer 550 can have the same material composition; in other examples those dielectric layers can have material compositions different from each other.

In some examples the light-emitting element 500 can include an electrically conductive cathode bonding layer 546 electrically coupled to the cathode electrical contact. In some such examples the cathode bonding layer 546 can include one or more of aluminum, silver, gold, or other metal or metallic alloy. In some examples the lateral dielectric layer 550 can electrically isolate the active and p-doped layers 502a/502b from the cathode bonding layer 546. In some examples in which the lateral dielectric layer 550 circumscribes only a portion of sidewalls of the n-doped layer 502c (e.g., as in FIGS. 6B and 6D), the cathode bonding layer 546 can be electrically coupled to the n-doped layer 502c by direct contact with at least a sidewall portion or peripheral portion of that layer and so act as the cathode electrical contact. In some other examples (e.g., as in FIGS. 6A and 6C), the lateral dielectric layer 550 can circumscribe sidewalls of the entire n-doped layer 502c. In such examples the electrically conductive cathode bonding layer 546 can be electrically coupled to the cathode electrical contact (e.g., a transparent electrode layer 544 on the light-exit surface 511), while the lateral dielectric layer 550 can separate the active, p-doped, and n-doped layers 502a/502b/502c from the cathode bonding layer. The transparent electrode layer 544, if present, and/or the TCO anode contact layer 534 (if present) can include one or more of indium tin oxide (ITO), indium zinc oxide (IZO), one or more other transparent conductive oxides (TCOs), or combinations or mixtures thereof. If both are present, they can include the same material(s) as one another or can include different material(s).

In some examples at least a portion of the cathode bonding layer 546 can be arranged to act as a lateral reflector at the side surfaces 513 of the LED. In some examples the lateral dielectric layer 550 can include a lateral reflector between the cathode bonding layer 546 and the side surfaces 513 of the LED; in some of those examples the lateral reflector can include a dielectric multilayer reflector or a distributed Bragg reflector. In some examples including lateral reflector in the lateral dielectric layer 550, the lateral reflector can include one or more materials among: one or more metals or metal alloys; doped or undoped silicon; one or more doped or undoped III-V, II-VI, or Group IV semiconductors; doped or undoped silicon oxide, nitride, or oxynitride; one or more doped or undoped semiconductor oxides, nitrides, or oxynitrides; one or more doped or undoped metal oxides, nitrides, or oxynitrides; one or more optical glasses; or one or more doped or undoped polymers.

A method for making any of the disclosed light-emitting elements 500 includes: (A) forming the p- and n-doped semiconductor layers 502b/502c with the active layer 502a between them; (B) forming the anode electrical contact electrically coupled to the p-doped semiconductor layer 502b; and (C) forming the cathode electrical contact electrically coupled to the n-doped semiconductor layer 502c. Such a method can include formation of any one or more or all of the structures, features, or arrangements discussed above.

Design or optimization one or more or all of, inter alia, the semiconductor layers 502a/502b/502c (e.g., refractive indices, thicknesses, doping levels), diode size or shape, separation between the anode electrical contact and the side surfaces 513, the dielectric layer(s) 540/550 (e.g., thickness, refractive index, reflector structure), or other structures or properties, can be performed (by calculation, simulation, or iterative designing/making/testing of prototypes or test devices) based on one or more selected figures-of-merit (FOMs). Device-performance-based FOMs that can be considered can include, e.g.: (i) extraction efficiency; (ii) total radiated emission; (iii) radiated angular distribution of the emitted light; (iv) fraction of radiated emission within a selected cone angle; (v) contrast ratio between adjacent pixel regions for light emission (discussed below), or (vi) other suitable or desirable FOMs. Instead or in addition, reduction of cost or manufacturing complexity can be employed as an FOM in a design or optimization process. Optimization for one FOM can result in non-optimal values for one or more other FOMs. Note that a device that is not necessarily fully optimized with respect to any FOM can nevertheless provide acceptable enhancement of one or more FOMs; such partly optimized devices fall within the scope of the present disclosure or appended claims.

FIG. 7 illustrates schematically a cross section of an example array 599 of light-emitting elements 500. Such an array 599 can be employed, e.g., as the array 200 (FIGS. 2A2C, 3A, 3B, or 4B), as a portion of the LED array and optical system 312 (FIG. 5A), as the light emitting array 321 (FIG. 5B), or the light sources 342 (FIG. 5C). In the example of FIG. 7 the light-emitting elements 500 are arranged as in the example of FIG. 6A; other suitably arranged light-emitting elements 500, including the examples of FIGS. 6B-6D, can be used to form an array 599. In some examples the light-emitting elements 500 of the array 599 can be arranged with their corresponding light-exit surfaces 511 in a substantially coplanar arrangement. In some examples the light-emitting elements 500 of the array 599 are arranged as direct emitters, so that the array 599 produces light output at only the wavelength λ₀. In some examples (not shown) the array 599 can include one or more one or more wavelength-converting structures of any suitable types or arrangements (e.g., one or more phosphors) positioned in a path of output light exiting the light-exit surfaces 511 of the light-emitting elements 500. The one or more wavelength-converting structures can be arranged to absorb at least a portion of the output light at the wavelength λ₀ and to emit light at one or more vacuum wavelengths that are each longer than λ₀, instead of or in addition to light at the wavelength λ₀. In some such wavelength-converted examples the elements 500 of the array 599 can all emit light at the same one or more wavelengths and at the same relative intensities among multiple wavelengths; in other such wavelength-converted examples the one or more wavelengths, or relative intensities among multiple wavelengths, can vary among the elements 500 of the array 599. In some examples the wavelength-converting structures can be arranged as discrete elements on each light-emitting element 500; in some other examples the wavelength-converting structures can be corresponding areas of a contiguous layer over multiple light-emitting elements 500, or over all of the light-emitting elements 500.

In some examples the multiple light-emitting elements 500 include discrete, structurally distinct elements 500 assembled together to form the array 599, e.g., on a circuit board or backplane 600 (discussed below). In other examples the multiple light-emitting elements 500 of the array 599 can be integrally formed together on a common substrate. In some instances that common substrate can remain as a component of the array 599 or backplane 600 (discussed below); in other examples the common substrate can be detached from the light-emitting elements 500 after they are attached to another structure, e.g., a circuit board or backplane 600 (discussed below). In some examples (e.g., as in FIG. 7) the corresponding n-doped layers 502c of the LEDs can be separated from one another with no direct electrical coupling between them; such examples can be integrally formed or assembled together. In other examples, corresponding n-doped layers 502c can form a single, continuous n-doped layer spanning multiple elements 500 or the entire array 599; such examples would be integrally formed.

In some examples nonzero spacing of the light-emitting elements 500 of the array 599 can be less than 50 μm, less than 30 μm, less than 20 μm, less than 10 μm, less than 8 μm, less than 5 μm, less than 3 μm, less than 2 μm, or less than 1 μm (while still large enough to enable operation of elements 500 to emit light). In some examples nonzero separation between adjacent light-emitting elements 500 of the array can be less than 10. μm, less than 5 μm, less than 2 μm, less than 1 μm, less than 0.5 μm, less than 0.2 μm, or less than 0.1 μm (while still large enough to enable independent operation of adjacent elements 500 of the array 599). In some examples the light-emitting elements 500 of the array 599 can exhibit a contrast ratio for emitted light exiting from adjacent light-emitting elements 500 that is greater than 5:1, greater than 10:1, greater than 20:1, greater than 50:1, greater than 100:1, or greater than 300:1.

In some examples the array 599 can include a set of electrically conductive anode traces or interconnects 636 connected to the anode electrical contacts via the anode bonding layers 536, or a set of electrically conductive cathode traces or interconnects 646 connected to the cathode electrical contacts via the cathode bonding layers 546, or both types of traces (shown in cross-section in FIG. 7). In some examples the traces or interconnects 636/646 can include one or more of aluminum, silver, gold, or one or more other metals or metal alloys. In some examples those traces or interconnects 636/646 can be formed on a circuit board, backplane, or integrated circuit 600 on which the light emitting elements 500 of the array 599 are mounted. In some examples those traces or interconnects 636/646 can be formed on a substrate on which the light emitting elements 500 of the array 599 are integrally formed. In some examples the array 599 can include a set of multiple independent electrically conductive anode traces or interconnects 636 connected to the corresponding anode electrical contacts, with each anode electrical contact being connected to a single corresponding one of the anode traces or interconnects 636 that is different from a corresponding anode trace or interconnect 636 connected to at least one other anode electrical contact. In some examples each anode electrical contact can be connected to a single corresponding one of the anode traces or interconnects 636 that is different from corresponding anode traces or interconnects 636 connected to all other anode electrical contacts (i.e., every light-emitting element 500 is independently addressable).

In some examples a drive circuit (e.g., as in FIGS. 4A through 5C) of any suitable type or arrangement (e.g., incorporating any suitable analog circuity, digital circuitry, general or application-specific integrated circuits, microprocessors, or combinations thereof) can be (i) connected to each of the cathode electrical contacts, e.g., by a corresponding cathode trace or interconnect 646, and (ii) connected to each of the anode electrical contacts by the anode electrical traces or interconnects 636. The drive circuit can be structured and connected so as to provide electrical drive current that flows through one or more of the elements 500 of the array 599 and causes the array 599 to emit light. In some examples the drive circuit can be further structured and connected so that (i) corresponding portions of the electrical drive current flow through one or more corresponding LEDs of the array as corresponding pixel currents, and (ii) each pixel current magnitude differs from the corresponding pixel current magnitude of at least one other of the LEDs of the array 599. In some examples the array 599 can be used by operating the drive circuit to deliver corresponding pixel currents to the elements 500 of the array 599 according to a desired spatial distribution of light emission intensity. A different distributions of pixels currents can be employed to produce different corresponding spatial distributions of light emission intensity from the array 599.

In some examples an array 599 can be made by (A) forming or assembling the multiple light-emitting elements 500 to form the array 599; (B) forming one or more electrical anode traces or interconnects 636 connected to the corresponding anode electrical contacts; and (C) connecting the drive circuit (i) to the corresponding anode electrical contacts using the anode traces or interconnects 636, and (ii) to the corresponding cathode electrical contacts, e.g., using the cathode traces or interconnects 646.

In addition to the preceding, the following example embodiments fall within the scope of the present disclosure or appended claims:

Example 1. A light-emitting element comprising: (a) a semiconductor light-emitting diode (LED) that includes a p-doped semiconductor layer, an n-doped semiconductor layer, and an active, light-emitting layer between the p-doped and n-doped layers, the LED being arranged for emitting light at a nominal emission vacuum wavelength λ₀ resulting from radiative recombination of charge carriers at the active layer, the LED having (i) a light-exit surface of the n-doped layer opposite the active layer, (ii) an anode contact surface of the p-doped layer opposite the active layer, the p-doped layer having a refractive index of n_{P} and a nonzero thickness less than 10λ₀/n_{P}, and (iii) side surfaces that laterally confine the p-doped layer, the active layer, and the n-doped layer, a largest transverse dimension of the LED being less than 30λ₀/n_{P}; (b) an anode electrical contact directly electrically coupled to the p-doped layer on only a central area of the anode contact surface, the central area being circumscribed by peripheral portions of the anode contact surface that lack direct electrical coupling to the anode electrical contact, separation between the side surfaces and lateral edges of the anode electrical contact being greater than λ₀/2n_{P}; and (c) a cathode electrical contact electrically coupled to the n-doped layer.

Example 2. The light-emitting element of Example 1, transverse dimensions of the light-emitting element, separation between the side surfaces and lateral edges of the anode electrical contact, and thickness of the p-doped layer resulting in a Purcell factor that is greater than 1.0, greater than 1.1, greater than 1.2, greater than 1.3, greater than 1.4, greater than 1.5, greater than 1.6, or greater than 1.7.

Example 3. The light-emitting element of any one of Examples 1 or 2, transverse dimensions of the light-emitting element, separation between the side surfaces and lateral edges of the anode electrical contact, and thickness of the p-doped layer resulting in extraction efficiency that is greater than 0.3, greater than 0.4, greater than 0.5, greater than 0.6, greater than 0.7, or greater than 0.8.

Example 4. The light-emitting element of any one of Examples 1 through 3, transverse dimensions of the light-emitting element, separation between the side surfaces and lateral edges of the anode electrical contact, and thickness of the p-doped layer resulting in overall light output efficiency that is greater than 0.5, greater than 0.6, greater than 0.7, or greater than 0.8.

Example 5. The light-emitting element of any one of Examples 1 through 4, transverse dimensions of the light-emitting element, separation between the side surfaces and lateral edges of the anode electrical contact, and thickness of the p-doped layer resulting in an angular distribution of output light in which more than 50% of the light output propagates within a cone half-angle that is less than 60°, that is less than 45°, less than 40°, less than 35°, or less than 30°.

Example 6. The light-emitting element of any one of Examples 1 through 4, transverse dimensions of the light-emitting element, separation between the side surfaces and lateral edges of the anode electrical contact, and thickness of the p-doped layer resulting in an angular distribution of output light in which more than 50% of the light output propagates within a solid angle that is less than 3 sr, less than 1.8 sr, less than 1.5 sr, less than 1.2 sr, or less than 1.0 sr.

Example 7. The light-emitting element of any one of Examples 1 through 6, the largest transverse dimension of the LED being less than 20λ₀/n_{P}, less than 10λ₀/n_{P}, less than 5λ₀/n_{P}, less than 3λ₀/n_{P}, or less than 2λ₀/n_{P}.

Example 8. The light-emitting element of any one of Examples 1 through 7, the largest transverse dimension of the LED being less than 10 μm, less than 5 μm, less than 3 μm, less than 2 μm, or less than 1 μm.

Example 9. The light-emitting element of any one of Examples 1 through 8, the separation between the side surfaces and lateral edges of the anode electrical contact being greater than λ₀/n_{P}, greater than 2λ₀/n_{P}, greater than 3λ₀/n_{P}, greater than 5λ₀/n_{P}, or greater than 10λ₀/n_{P}.

Example 10. The light-emitting element of any one of Examples 1 through 9, separation between lateral edges of the anode electrical contact and the side surfaces being greater than 0.02 μm, greater than 0.05 μm, greater than 0.1 μm, greater than 0.2 μm, greater than 0.3 μm, greater than 0.5 μm, or greater than 1 μm.

Example 11. The light-emitting element of any one of Examples 1 through 10, the central area occupying a non-zero fraction of total area of the anode contact surface of the p-doped layer that is less than 70%, less than 50%, less than 40%, less than 30%, less than 20%, or less than 10%.

Example 12. The light-emitting element of any one of Examples 1 through 11,nonzero thickness of the p-doped layer being less than 5λ₀/n_{P}, less than 3λ₀/n_{P}, less than 2λ₀/n_{P}, less than λ₀/n_{P}, less than λ₀/2n_{P}, less than λ₀/3n_{P}, or less than λ₀/5n_{P}.

Example 13. The light-emitting element of any one of Examples 1 through 12, nonzero thickness of the p-doped layer being less than 1.5 μm, less than 1.0 μm, less than 0.5 μm, less than 0.3 μm, less than 0.2 μm, less than 0.1 μm, less than 0.05 μm, or less than 0.04 μm, less than 0.03 μm, or less than 0.02 μm.

Example 14. The light-emitting element of any one of Examples 1 through 13 further comprising an electrically insulating back dielectric layer on the peripheral portions of the anode contact surface that lack direct electrical coupling to the anode electrical contact.

Example 15. The light-emitting element of Example 14, the back dielectric layer comprising material of the p-doped layer that is oxidized or passivated.

Example 16. The light-emitting element of Example 14, the back dielectric layer comprising material different from material of the p-doped layer and different from oxidized or passivated material of the p-doped layer.

Example 17. The light-emitting element of any one of Examples 14 through 16, material of the anode electrical contact extending through the back dielectric layer and being directly electrically coupled to the central area of the anode contact surface.

Example 18. The light-emitting element of any one of Examples 14 through 16, non-oxidized and non-passivated material of the p-doped layer extending through the back dielectric layer to form the central area of the anode contact surface directly electrically coupled to the anode electrical contact.

Example 19. The light-emitting element of any one of Examples 14 through 18, the back dielectric layer including one or more materials among: doped or undoped silicon oxide, nitride, or oxynitride; one or more doped or undoped semiconductor oxides, nitrides, or oxynitrides; one or more doped or undoped metal oxides, nitrides, or oxynitrides; one or more optical glasses; or one or more doped or undoped polymers.

Example 20. The light-emitting element of any one of Examples 1 through 19, the anode electrical contact comprising a metal layer in direct contact with the central area of the anode contact surface, the metal layer including one or more of aluminum, silver, gold, or other metal or metallic alloy.

Example 21. The light-emitting element of any one of Examples 1 through 19, the anode electrical contact comprising a transparent conductive layer in direct contact with the central area of the anode contact surface, the transparent conductive layer including one or more of indium tin oxide (ITO), indium zonc oxide (IZO), another transparent conductive oxide (TCO), or combinations or mixtures thereof.

Example 22. The light-emitting element of any one of Examples 1 through 21 further comprising an electrically conductive anode bonding layer electrically coupled to the anode contact surface by the anode electrical contact and electrically isolated from the active and n-doped layers.

Example 23. The light-emitting element of Example 22, the anode electrical contact being a portion of the anode bonding layer in direct contact with the central area of the anode contact surface.

Example 24. The light-emitting element of any one of Examples 22 or 23, the anode bonding layer including one or more of aluminum, silver, gold, or other metal or metallic alloy.

Example 25. The light-emitting element of any one of Examples 14 through 24 further comprising an electrically insulating lateral dielectric layer on at least portions of the side surfaces, the lateral dielectric layer being contiguous with the back dielectric layer and circumscribing the entire p-doped layer, the entire active layer, and at least a portion of the n-doped layer.

Example 26. The light-emitting element of any one of Examples 1 through 24 further comprising an electrically insulating lateral dielectric layer on at least portions of the side surfaces, the lateral dielectric layer circumscribing the entire p-doped layer, the entire active layer, and at least a portion of the n-doped layer.

Example 27. The light-emitting element of any one of Examples 25 or 26, the lateral dielectric layer including one or more materials among: doped or undoped silicon oxide, nitride, or oxynitride; one or more doped or undoped semiconductor oxides, nitrides, or oxynitrides; one or more doped or undoped metal oxides, nitrides, or oxynitrides; one or more optical glasses; or one or more doped or undoped polymers.

Example 28. The light-emitting element of any one of Examples 25 through 27 further comprising an electrically conductive cathode bonding layer electrically coupled to the cathode electrical contact, the lateral dielectric layer electrically isolating the p-doped and active layers from the cathode bonding layer, the cathode bonding layer being electrically coupled to the n-doped layer by direct contact with at least a sidewall portion or peripheral portion thereof so as to act as the cathode electrical contact.

Example 29. The light-emitting element of any one of Examples 25 through 27, the lateral dielectric layer circumscribing the entire n-doped layer.

Example 30. The light-emitting element of Example 29 further comprising an electrically conductive cathode bonding layer electrically coupled to the cathode electrical contact, the lateral dielectric layer electrically isolating the p-doped and active layers from the cathode bonding layer and separating the cathode bonding layer from side walls of the n-doped layer.

Example 31. The light-emitting element of any one of Examples 28 through 30, at least a portion of the cathode bonding layer being arranged to act as a lateral reflector at the side surfaces of the LED.

Example 32. The light-emitting element of any one of Examples 28 through 31, the cathode bonding layer including one or more of aluminum, silver, gold, or other metal or metallic alloy.

Example 33. The light-emitting element of any one of Examples 28 through 32, the lateral dielectric layer including a lateral reflector between the bonding layer and the side surfaces of the LED.

Example 34. The light-emitting element of Example 33, the lateral reflector including a dielectric multilayer reflector or a distributed Bragg reflector.

Example 35. The light-emitting element of any one of Examples 33 or 34, the lateral reflector including one or more materials among: one or more metals or metal alloys; doped or undoped silicon; one or more doped or undoped III-V, II-VI, or Group IV semiconductors; doped or undoped silicon oxide, nitride, or oxynitride; one or more doped or undoped semiconductor oxides, nitrides, or oxynitrides; one or more doped or undoped metal oxides, nitrides, or oxynitrides; one or more optical glasses; or one or more doped or undoped polymers.

Example 36. The light-emitting element of any one of Examples 25 through 32, the lateral dielectric layer comprising a single layer of a single dielectric material.

Example 37. The light-emitting element of any one of Examples 1 through 36, the cathode electrical contact including a transparent electrode layer in direct contact with at least a portion of the light-exit surface, the transparent electrode layer including one or more of indium tin oxide, indium zinc oxide, one or more other transparent conductive oxides, or combinations or mixtures thereof.

Example 38. The light-emitting element of any one of Examples 1 through 37, the LED including one or more doped or undoped III-V, II-VI, or Group IV semiconductor materials or alloys or mixtures thereof.

Example 39. The light-emitting element of any one of Examples 1 through 38, the nominal emission vacuum wavelength λ₀ being greater than 0.2 μm, greater than 0.4 μm, greater than 0.8 μm, less than 10 μm, less than 3 μm, or less than 1 μm.

Example 40. The light-emitting element of any one of Examples 1 through 39, the active layer including one or more p-n junctions, one or more quantum wells, one or more multi-quantum wells, or one or more quantum dots.

Example 41. The light-emitting element of any one of Examples 1 through 40, total nonzero thickness of the layers of the LED being less than 10. μm, less than 5 μm, less than 3 μm, less than 2 μm, less than 1.5 μm, or less than 1.0 μm.

Example 42. The light-emitting element of any one of Examples 1 through 41 further comprising a wavelength-converting structure positioned in a path of output light exiting the light-exit surface and arranged to absorb at least a portion of the output light at the wavelength λ₀ and to emit light at one or more vacuum wavelengths that are each longer than λ₀.

Example 43. A method for making the light-emitting element of any one of Examples 1 through 42, the method comprising: (A) forming the p- and n-doped semiconductor layers with the active layer between them; (B) forming the anode electrical contact electrically coupled to the p-doped semiconductor layer; and (C) forming the cathode electrical contact electrically coupled to the n-doped semiconductor layer.

Example 44. A light-emitting array comprising multiple light-emitting elements of any one of Examples 1 through 42.

Example 45. The light-emitting array of Example 44, the multiple light-emitting elements of the array being arranged with corresponding light-exit surfaces thereof in a substantially coplanar arrangement.

Example 46. The light-emitting array of any one of Examples 44 or 45, the corresponding n-doped layers of the LEDs being separated from one another with no direct electrical coupling between corresponding n-doped layers thereof.

Example 47. The light-emitting array of Example 46, the multiple light-emitting elements comprising discrete, structurally distinct elements assembled together to form the array.

Example 48. The light-emitting array of any one of Examples 44 through 46, the multiple light-emitting elements of the array being integrally formed together on a common substrate.

Example 49. The light-emitting array of any one of Examples 44 or 45, the multiple light-emitting elements of the array being integrally formed together on a common substrate, the corresponding n-doped layers of the LEDs forming a single, continuous n-doped layer spanning the array.

Example 50. The light-emitting array of any one of Examples 44 through 49, nonzero spacing of the light-emitting elements of the array being less than 50 μm, less than 30 μm, less than 20 μm, less than 10 μm, less than 8 μm, less than 5 μm, less than 3 μm, less than 2 μm, or less than 1 μm.

Example 51. The light-emitting array of any one of Examples 44 through 50, nonzero separation between adjacent light-emitting elements of the array being less than 10 μm, less than 5 μm, less than 2 μm, less than 1 μm, less than 0.5 μm, less than 0.2 μm, or less than 0.1 μm.

Example 52. The light-emitting array of any one of Examples 44 through 51, the light-emitting elements of the array exhibiting a contrast ratio for emitted light exiting from adjacent light-emitting elements that is greater than 5:1, greater than 10:1, greater than 20:1, greater than 50:1, greater than 100:1, or greater than 300:1.

Example 53. The light-emitting array of any one of Examples 44 through 52 further comprising one or more wavelength-converting structures positioned in a path of output light exiting the light-exit surfaces of the light-emitting elements and arranged to absorb at least a portion of the output light at the wavelength λ₀ and to emit light at one or more vacuum wavelengths that are each longer than λ₀.

Example 54. The light-emitting array of any one of Examples 44 through 53, further comprising a set of multiple independent electrically conductive traces or interconnects connected to the corresponding anode electrical contacts, each anode electrical contact being connected to a single corresponding one of the traces or interconnects that is different from a corresponding trace or interconnect connected to at least one other anode electrical contact.

Example 55. The light-emitting element of Example 54, the one or more electrically conductive traces or interconnects including one or more of aluminum, silver, gold, or one or more other metals or metal alloys.

Example 56. The light-emitting array of any one of Examples 54 or 55 further comprising a circuit board, backplane, or integrated circuit on which are positioned the one or more electrically conductive traces or interconnects, the multiple light-emitting elements of the array being positioned on the circuit board, backplane, or integrated circuit.

Example 57. The light-emitting array of any one of Examples 54 through 56, each anode electrical contact being connected to a single corresponding one of the traces or interconnects that is different from corresponding traces or interconnects connected to all other anode electrical contacts.

Example 58. The light-emitting array of any one of Examples 54 through 57 further comprising a drive circuit (i) connected to each of the cathode electrical contacts, and (ii) connected to each of the anode electrical contacts by the electrical traces or interconnects, the drive circuit being structured and connected so as to provide electrical drive current that flows through one or more of the elements of the array and causes the array to emit light, and that is further structured and connected so that (i) corresponding portions of the electrical drive current flow through one or more corresponding LEDs as corresponding pixel currents, and (ii) each pixel current magnitude differs from the corresponding pixel current magnitude of at least one other of the LEDs of the array.

Example 59. A method for using the light-emitting array of Example 58, the method comprising: (A) selecting a first specified spatial distribution of pixel current magnitudes; (B) operating the drive circuit to provide the first specified spatial distribution of pixel current magnitudes to the LEDs of the array, causing the array to emit light according to a corresponding first spatial distribution of light emission intensity across the array; (C) selecting a second specified spatial distribution of pixel current magnitudes that differs from the first specified spatial distribution of pixel current magnitudes; and (D) operating the drive circuit to provide the second specified spatial distribution of pixel current magnitudes to the LEDs of the array, causing the array to emit light according to a corresponding second spatial distribution of light emission intensity across the array that differs from the first spatial distribution of light emission intensity.

Example 60. A method for making the light-emitting array of Example 58, the method comprising: (A) forming or assembling the multiple light-emitting elements to form the array; (B) forming one or more electrical traces or interconnects connected to the corresponding anode electrical contacts; and (C) connecting the drive circuit (i) to the corresponding anode electrical contacts using the electrical traces or interconnects, and (ii) to the corresponding cathode electrical contacts.

This disclosure is illustrative and not limiting. Further modifications will be apparent to one skilled in the art in light of the present disclosure and are intended to fall within the scope of the present disclosure or appended claims. It is intended that equivalents of the disclosed example embodiments and methods, or modifications thereof, shall fall within the scope of the present disclosure or appended claims.

In the foregoing Detailed Description, various features may be grouped together in several example embodiments for the purpose of streamlining the disclosure. This method of disclosure is not to be interpreted as reflecting an intention that any claimed embodiment requires more features than are expressly recited in the corresponding claim. Rather, as the appended claims reflect, inventive subject matter may lie in less than all features of a single disclosed example embodiment. Therefore, the present disclosure shall be construed as implicitly disclosing any embodiment having any suitable subset of one or more features-which features are shown, described, or claimed in the present application-including those subsets that may not be explicitly disclosed herein. A “suitable” subset of features includes only features that are neither incompatible nor mutually exclusive with respect to any other feature of that subset. Accordingly, the appended claims are hereby incorporated in their entirety into the Detailed Description, with each claim standing on its own as a separate disclosed embodiment. In addition, each of the appended dependent claims shall be interpreted, only for purposes of disclosure by said incorporation of the claims into the Detailed Description, as if written in multiple dependent form and dependent upon all preceding claims with which it is not inconsistent. It should be further noted that the cumulative scope of the appended claims can, but does not necessarily, encompass the whole of the subject matter disclosed in the present application.

The following interpretations shall apply for purposes of the present disclosure and appended claims. The words “comprising,” “including,” “having,” and variants thereof, wherever they appear, shall be construed as open ended terminology, with the same meaning as if a phrase such as “at least” were appended after each instance thereof, unless explicitly stated otherwise. The article “a” shall be interpreted as “one or more” unless “only one,” “a single,” or other similar limitation is stated explicitly or is implicit in the particular context; similarly, the article “the” shall be interpreted as “one or more of the” unless “only one of the,” “a single one of the,” or other similar limitation is stated explicitly or is implicit in the particular context. The conjunction “or” is to be construed inclusively unless: (i) it is explicitly stated otherwise, e.g., by use of “either . . . or,” “only one of,” or similar language; or (ii) two or more of the listed alternatives are understood or disclosed (implicitly or explicitly) to be incompatible or mutually exclusive within the particular context. In that latter case, “or” would be understood to encompass only those combinations involving non-mutually-exclusive alternatives. In one example, each of “a dog or a cat,” “one or more of a dog or a cat,” and “one or more dogs or cats” would be interpreted as one or more dogs without any cats, or one or more cats without any dogs, or one or more of each.

For purposes of the present disclosure or appended claims, when a numerical quantity is recited (with or without terms such as “about,” “about equal to,” “substantially equal to,” “greater than about,” “less than about,” and so forth), standard conventions pertaining to measurement precision, rounding error, and significant digits shall apply, unless a differing interpretation is explicitly set forth. For null quantities described by phrases such as “substantially prevented,” “substantially absent,” “substantially eliminated,” “about equal to zero,” “negligible,” and so forth, each such phrase shall denote the case wherein the quantity in question has been reduced or diminished to such an extent that, for practical purposes in the context of the intended operation or use of the disclosed or claimed apparatus or method, the overall behavior or performance of the apparatus or method does not differ from that which would have occurred had the null quantity in fact been completely removed, exactly equal to zero, or otherwise exactly nulled.

For purposes of the present disclosure and appended claims, any labelling of elements, steps, limitations, or other portions of an embodiment, example, or claim (e.g., first, second, third, etc., (a), (b), (c), etc., or (i), (ii), (iii), etc.) is only for purposes of clarity, and shall not be construed as implying any sort of ordering or precedence of the portions so labelled. If any such ordering or precedence is intended, it will be explicitly recited in the embodiment, example, or claim or, in some instances, it will be implicit or inherent based on the specific content of the embodiment, example, or claim. In the appended claims, if the provisions of 35 USC §112(f) are desired to be invoked in an apparatus claim, then the word “means” will appear in that apparatus claim. If those provisions are desired to be invoked in a method claim, the words “a step for” will appear in that method claim. Conversely, if the words “means” or “a step for” do not appear in a claim, then the provisions of 35 USC §112(f) are not intended to be invoked for that claim.

If any one or more disclosures are incorporated herein by reference and such incorporated disclosures conflict in part or whole with, or differ in scope from, the present disclosure, then to the extent of conflict, broader disclosure, or broader definition of terms, the present disclosure controls. If such incorporated disclosures conflict in part or whole with one another, then to the extent of conflict, the later-dated disclosure controls.

The Abstract is provided as required as an aid to those searching for specific subject matter within the patent literature. However, the Abstract is not intended to imply that any elements, features, or limitations recited therein are necessarily encompassed by any particular claim. The scope of subject matter encompassed by each claim shall be determined by the recitation of only that claim.

What is claimed is:

1. A light-emitting element comprising:
a semiconductor light-emitting diode (LED) that includes a p-doped semiconductor layer, an n-doped semiconductor layer, and an active, light-emitting layer between the p-doped and n-doped layers, the LED being arranged for emitting light at a nominal emission vacuum wavelength λ₀ resulting from radiative recombination of charge carriers at the active layer, the LED having (i) a light-exit surface of the n-doped layer opposite the active layer, (ii) an anode contact surface of the p-doped layer opposite the active layer, the p-doped layer having a refractive index of n_{P} and a nonzero thickness less than 10λ₀/n_{P}, and (iii) side surfaces that laterally confine the p-doped layer, the active layer, and the n-doped layer, a largest transverse dimension of the LED being less than 30λ₀/n_{P};
an anode electrical contact directly electrically coupled to the p-doped layer on only a central area of the anode contact surface, the central area being circumscribed by peripheral portions of the anode contact surface that lack direct electrical coupling to the anode electrical contact, separation between the side surfaces and lateral edges of the anode electrical contact being greater than λ₀/2n_{P}; and
a cathode electrical contact electrically coupled to the n-doped layer.

2. The light-emitting element of claim 1, transverse dimensions of the light-emitting element, separation between the side surfaces and lateral edges of the anode electrical contact, and thickness of the p-doped layer resulting in a Purcell factor that is greater than 1.0.

3. The light-emitting element of claim 1, transverse dimensions of the light-emitting element, separation between the side surfaces and lateral edges of the anode electrical contact, and thickness of the p-doped layer resulting in (i) extraction efficiency that is greater than 0.3, or (ii) overall light output efficiency that is greater than 0.5.

4. The light-emitting element of claim 1, transverse dimensions of the light-emitting element, separation between the side surfaces and lateral edges of the anode electrical contact, and thickness of the p-doped layer resulting in an angular distribution of output light in which more than 50% of the light output propagates (i) within a cone half-angle that is less than 60°, or (ii) within a solid angle that is less than 3 sr.

5. The light-emitting element of claim 1, the largest transverse dimension of the LED being (i) less than 20λ₀/n_{P}, or (ii) less than 10 μm.

6. The light-emitting element of claim 1, the separation between the side surfaces and lateral edges of the anode electrical contact being (i) greater than λ₀/n_{P}, or (ii) greater than 0.1 μm.

7. The light-emitting element of claim 1, the central area occupying a non-zero fraction of total area of the anode contact surface of the p-doped layer that is less than 70%.

8. The light-emitting element of claim 1 wherein (i) nonzero thickness of the p-doped layer is less than 5λ₀/n_{P}; (ii) nonzero thickness of the p-doped layer is less than 0.5 μm; or (iii) total nonzero thickness of the layers of the LED is less than 5 μm.

9. The light-emitting element of claim 1 further comprising an electrically insulating back dielectric layer on the peripheral portions of the anode contact surface that lack direct electrical coupling to the anode electrical contact, wherein either (i) material of the anode electrical contact extends through the back dielectric layer and is directly electrically coupled to the central area of the anode contact surface, or (ii) non-oxidized and non-passivated material of the p-doped layer extends through the back dielectric layer to form the central area of the anode contact surface directly electrically coupled to the anode electrical contact.

10. The light-emitting element of claim 1, the anode electrical contact comprising a metal layer in direct contact with the central area of the anode contact surface, the metal layer including one or more of aluminum, silver, gold, or other metal or metallic alloy.

11. The light-emitting element of claim 1, the anode electrical contact comprising a transparent conductive layer in direct contact with the central area of the anode contact surface, the transparent conductive layer including one or more of indium tin oxide (ITO), indium zonc oxide (IZO), another transparent conductive oxide (TCO), or combinations or mixtures thereof.

12. The light-emitting element of claim 1 further comprising an electrically conductive anode bonding layer electrically coupled to the anode contact surface by the anode electrical contact and electrically isolated from the active and n-doped layers.

13. The light-emitting element of claim 1 further comprising an electrically insulating lateral dielectric layer on at least portions of the side surfaces, the lateral dielectric layer circumscribing the entire p-doped layer, the entire active layer, and at least a portion of the n-doped layer.

14. The light-emitting element of claim 13 further comprising an electrically conductive cathode bonding layer electrically coupled to the cathode electrical contact, the lateral dielectric layer electrically isolating the p-doped and active layers from the cathode bonding layer, the cathode bonding layer being electrically coupled to the n-doped layer by direct contact with at least a sidewall portion or peripheral portion thereof so as to act as the cathode electrical contact.

15. The light-emitting element of claim 14, the lateral dielectric layer separating the cathode bonding layer from at least portions of side walls of the n-doped layer, at least a portion of the cathode bonding layer being arranged to act as a lateral reflector at the side surfaces of the LED.

16. The light-emitting element of claim 14, the lateral dielectric layer circumscribing the entire n-doped layer and separating the cathode bonding layer from side walls of the n-doped layer.

17. The light-emitting element of claim 13 further comprising an electrically conductive cathode bonding layer electrically coupled to the cathode electrical contact, the lateral dielectric layer electrically isolating the p-doped and active layers from the cathode bonding layer and separating the cathode bonding layer from at least portions of side walls of the n-doped layer, the lateral dielectric layer including a lateral reflector between the bonding layer and the side surfaces of the LED.

18. The light-emitting element of claim 1, the cathode electrical contact including a transparent electrode layer in direct contact with at least a portion of the light-exit surface, the transparent electrode layer including one or more of indium tin oxide, indium zinc oxide, one or more other transparent conductive oxides, or combinations or mixtures thereof.

19. A method for making the light-emitting element of claim 1, the method comprising:
(A) forming the p- and n-doped semiconductor layers with the active layer between them;
(B) forming the anode electrical contact electrically coupled to the p-doped semiconductor layer; and
(C) forming the cathode electrical contact electrically coupled to the n-doped semiconductor layer.

20. A light-emitting array comprising multiple light-emitting elements of claim 1 wherein:
(i) nonzero spacing of the light-emitting elements of the array is less than 50 μm;
(ii) nonzero separation between adjacent light-emitting elements of the array is less than 10 μm; and
(iii) the light-emitting elements of the array exhibit a contrast ratio for emitted light exiting from adjacent light-emitting elements that is greater than 5:1.
